(19) United States
(12) Patent Application Publication
(10) Pub. No.: US 2016/0351711 A1
(43) Pub. Date: Dec. 1, 2016

(54) SEMICONDUCTOR DEVICE HAVING AT LEAST ONE STRESSOR AND METHOD OF MANUFACTURING THE SAME

(71) Applicant: Samsung Electronics Co., Ltd., Suwon-si (KR)

(72) Inventors: Byeong-ju BAE, Hwaseong-si (KR); Seung-heon LEE, Seoul (KR); Byoung-deog CHOI, Suwon-si (KR)

(21) Appl. No.: 15/138,661

(22) Filed: Apr. 26, 2016

(30) Foreign Application Priority Data
May 27, 2015 (KR) 10-2015-0073929

(51) Int. Cl. H01L 29/78; H01L 27/118; H01L 21/02; H01L 29/423; H01L 21/28

(52) U.S. Cl. CPC H01L 29/7842; H01L 29/4236; H01L 21/28247; H01L 21/02274; H01L 27/11807

(57) ABSTRACT

A method of manufacturing a semiconductor device includes forming a word line trench in an active region, forming a gate dielectric layer to cover at least a portion of the word line trench, forming a word line within the word line trench to define a capping trench, and/or forming a stressor having a compressive stress within the capping trench. The stressor is formed by using a plasma source.

### CROSS-REFERENCE TO RELATED APPLICATION

This application claims the benefit of Korean Patent Application No. 10-2015-0073929, filed on May 27, 2015, in the Korean Intellectual Property Office, the disclosure of which is incorporated herein in its entirety by reference.

### BACKGROUND

The inventive concepts relate to a semiconductor device and a method of manufacturing the same, and more particularly, to a semiconductor device including a capping layer having at least one stressor and a method of manufacturing the same.

Research has been conducted into a buried word line cell array transistor (BCAT) in which word lines are buried under a surface of a silicon substrate and formed at small intervals to reduce a cell area. In recent years, with an increase in the integration density of semiconductor devices, current characteristics with respect to transistor operations may be degraded. Thus, it is necessary to develop a technique for preventing or reducing degradation of electrical characteristics of a downscaled semiconductor device and maintaining reliability of the downscaled semiconductor device.

### SUMMARY

The inventive concepts provide a semiconductor device, which may be miniaturized or reduced to prevent or reduce degradation of electrical properties and/or maintain reliability.

According to an aspect of the inventive concepts, there is provided a method of manufacturing a semiconductor device. The method includes forming a word line trench in an active region, forming a gate dielectric layer to cover at least a portion of the word line trench, forming a word line within the word line trench to define a capping trench, and/or forming a stressor having a compressive stress within the capping trench. The stressor is formed by using a plasma source.

In at least one example embodiment, the stressor may be formed by using at least one of a plasma-enhanced chemical vapor deposition (PECVD) process, a high-density plasma CVD (HDP CVD) process, an inductively coupled plasma CVD (ICP CVD) process, and a capacitor-coupled plasma CVD (CCP CVD) process. In at least one example embodiment, the stressor may have a compressive stress of about 0.1 GPa to about 3 GPa.

In at least one example embodiment, the formation of the stressor may include forming a first stressor layer to cover the capping trench, etching the first stressor layer, and forming a second stressor layer on the etched first stressor layer.

In at least one example embodiment, the method may further include performing a planarization process on the first and second stressor layers to expose a top surface of the active region.

In at least one example embodiment, the formation of the stressor may include forming a stressor layer by using a plasma-enhanced atomic layer deposition (PEALD) process to cover the capping trench, and performing a planarization process on the stressor layer to expose a top surface of the active region.

According to another aspect of the inventive concepts, there is provided a method of manufacturing a semiconductor device. The method includes forming a word line trench in an active region, forming a gate dielectric layer to cover at least a portion of the word line trench, forming a word line within the word line trench to define a capping trench, and/or forming a capping layer to cover the capping trench. The capping layer includes a first stressor and a second stressor having different stresses, and at least one of the first and second stressors is formed by using a plasma source.

In at least one example embodiment, a sidewall of the first stressor may be inclined.

In at least one example embodiment, one of the first and second stressors may have a compressive stress, and the other may have a tensile stress.

In at least one example embodiment, the first stressor may have a first compressive stress, and the second stressor may have a second compressive stress different from the first compressive stress.

In at least one example embodiment, one of the first and second stressors may be formed by using at least one of a PECVD process, an HDP CVD process, an ICP CVD process, a CCP CVD process, and a PEALD, and the other one of the first and second stressors is formed by a thermal atomic layer deposition (ALD) process.

In at least one example embodiment, the formation of the capping layer may include forming a first stressor layer to cover the capping trench, etching the first stressor layer, forming a second stressor layer on the etched first stressor layer, the second stressor layer having a different stress from the first stressor layer, and performing a planarization process on the first and second stressor layers to form the first and second stressors.

In at least one example embodiment, the formation of the capping layer may include forming a first stressor layer to cover the capping trench, etching back the first stressor layer to form the first stressor, and forming the second stressor on the first stressor.

In at least one example embodiment, the first stressor may have a compressive stress, and a side surface of the first stressor may be in contact with the gate dielectric layer.

In at least one example embodiment, the first stressor may have a compressive stress, and a side surface of the first stressor may be in contact with the word line trench.

According to another aspect of the inventive concepts, there is provided a method of manufacturing a semiconductor device. The method includes forming a plurality of active regions in a semiconductor substrate, each active region having a major axis in a first direction and a minor axis in a second direction, the active regions repetitively arranged apart from one another in the first direction and the second direction, forming a device isolation layer to define the plurality of active regions, forming a plurality of word line trenches extending across the plurality of active regions and the device isolation layer, forming a gate dielectric layer to cover at least a portion of each of the word line trenches, forming a plurality of word lines within the word line trenches, the word lines having top surfaces positioned at a lower level than top surfaces of the active regions, and/or forming a capping layer to cover the top surface of each of the word lines. In at least one example embodiment, the capping layer includes a plurality of stressors, at least one of the plurality of stressors has a compressive stress, and at least one of the plurality of stressors is formed by using a plasma source.

In at least one example embodiment, at least one of the plurality of stressors may be formed without a seam.

In at least one example embodiment, at least one of the plurality of stressors may be in contact with the top surface of the word line.

In at least one example embodiment, each of the word lines may include a first gate electrode layer and a second gate electrode layer formed of a different material from the first gate electrode layer.

In at least one example embodiment, each of the word lines may have a bulb-type structure having a circular lower section or a structure having a U-shape.

According to another aspect of the inventive concepts, there is provided a method of manufacturing a semiconductor device. The method includes forming a trench, for example a word line trench, in an active region, forming a dielectric layer, for example a gate dielectric layer, to fill at least a portion of the trench, forming an address line, for example a bit line or a word line, within the trench to define a shallower capping trench, and using a plasma source to form at least one stressor having a compressive stress within the shallower capping trench.

In at least one example embodiment, plasma source may be at least one of a plasma-enhanced chemical vapor deposition (PECVD) source, a high-density plasma CVD (HDP CVD) source, an inductively coupled plasma CVD (ICP CVD) source, and a capacitor-coupled plasma CVD (CCP CVD) source.

In at least one example embodiment, at least one stressor may have a compressive stress of about 0.1 GPa to about 3 GPa.

In at least one example embodiment, forming of the at least one stressor may include forming a first stressor layer in the shallower capping trench, etching the first stressor layer, and forming a second stressor layer on the etched first stressor layer.

In at least one example embodiment, one of the first and second stressor layers may have a compressive stress and the other of the first and second stressor layers may have a tensile stress.

### BRIEF DESCRIPTION OF THE DRAWINGS

Example embodiments of the inventive concepts will be more clearly understood from the following detailed description taken in conjunction with the accompanying drawings in which:

FIG. 1A is a plan view of examples of some elements of a semiconductor device according to an example embodiment;

FIG. 1B is a cross-sectional view taken along a line B1-B1 of FIG. 1A;

FIG. 2 is a cross-sectional view of examples of some elements of a semiconductor device according to another example embodiment;

FIG. 3 is a cross-sectional view of examples of some elements of a semiconductor device according to another example embodiment;

FIG. 4 is a cross-sectional view of examples of some elements of a semiconductor device according to another example embodiment;

FIG. 5 is a cross-sectional view of examples of some elements of a semiconductor device according to another example embodiment;

FIG. 6 is a cross-sectional view of examples of some elements of a semiconductor device according to another example embodiment;

FIG. 7 is a cross-sectional view of examples of some elements of a semiconductor device according to another example embodiment;

FIG. 8 is a cross-sectional view of examples of some elements of a semiconductor device according to another example embodiment;

FIGS. 9 and 10 are graph showing improvements in current characteristics of a semiconductor device according to example embodiments;

FIGS. 11A to 11F are cross-sectional views of process operations of a method of manufacturing a semiconductor device according to an example embodiment;

FIGS. 12A to 12E are cross-sectional views of process operations of a method of manufacturing a capping layer according to an example embodiment;

FIGS. 13A to 13E are cross-sectional views of process operations of a method of manufacturing a capping layer according to another example embodiment;

FIGS. 14A to 14D are cross-sectional views of process operations of a method of manufacturing a capping layer according to another example embodiment;

FIGS. 15A to 15C are cross-sectional views of process operations of a method of manufacturing a capping layer according to another example embodiment;

FIGS. 16A to 16D are cross-sectional views of process operations of a method of manufacturing a capping layer according to another example embodiment;

FIGS. 17A to 17D are cross-sectional views of process operations of a method of manufacturing a capping layer according to another example embodiment;

FIG. 18 is a diagram of a memory module including a semiconductor device according to various example embodiments;

FIG. 19 is a diagram of a memory card including a semiconductor device according to various example embodiments;

FIG. 20 is a diagram of an electronic system including at least one of semiconductor devices according to various example embodiments;

FIG. 21 is a diagram of another electronic system including at least one of semiconductor devices according to various example embodiments; and

FIG. 22 is a schematic diagram of a wireless mobile phone including a semiconductor device according to various example embodiments.

### DETAILED DESCRIPTION OF EXAMPLE EMBODIMENTS

As used herein, the term “and/or” includes any and all combinations of one or more of the associated listed items. Expressions such as “at least one of,” when preceding a list of elements, modify the entire list of elements and do not modify the individual elements of the list.

The inventive concepts will now be described more fully hereinafter with reference to the accompanying drawings, in which example embodiments of the inventive concepts are shown Like reference numerals in the drawings denote like elements, and thus descriptions thereof will be omitted.

These inventive concepts may, however, be embodied in different forms and should not be construed as limited to the embodiments set forth herein. Rather, these embodiments are provided so that this disclosure is thorough and complete and fully conveys the scope of the inventive concepts to one of ordinary skill in the art.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concepts.

Unless otherwise defined, all terms (including technical and scientific terms) used herein have the same meaning as commonly understood by one of ordinary skill in the art to which these inventive concepts belong. It will be further understood that terms, such as those defined in commonly used dictionaries, should be interpreted as having a meaning that is consistent with their meaning in the context of the relevant art and this specification and will not be interpreted in an idealized or overly formal sense unless explicitly so defined herein.

When some embodiments may be embodied otherwise, respective process steps described herein may be performed otherwise. For example, two process steps described in a sequential order may be performed substantially the same time or in reverse order.

Variations from the shapes of the illustrations as a result, for example, of manufacturing techniques and/or tolerances, are to be expected. Thus, embodiments of the inventive concepts should not be construed as limited to the particular shapes of regions illustrated herein but are to include deviations in shapes that result, for example, from manufacturing.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

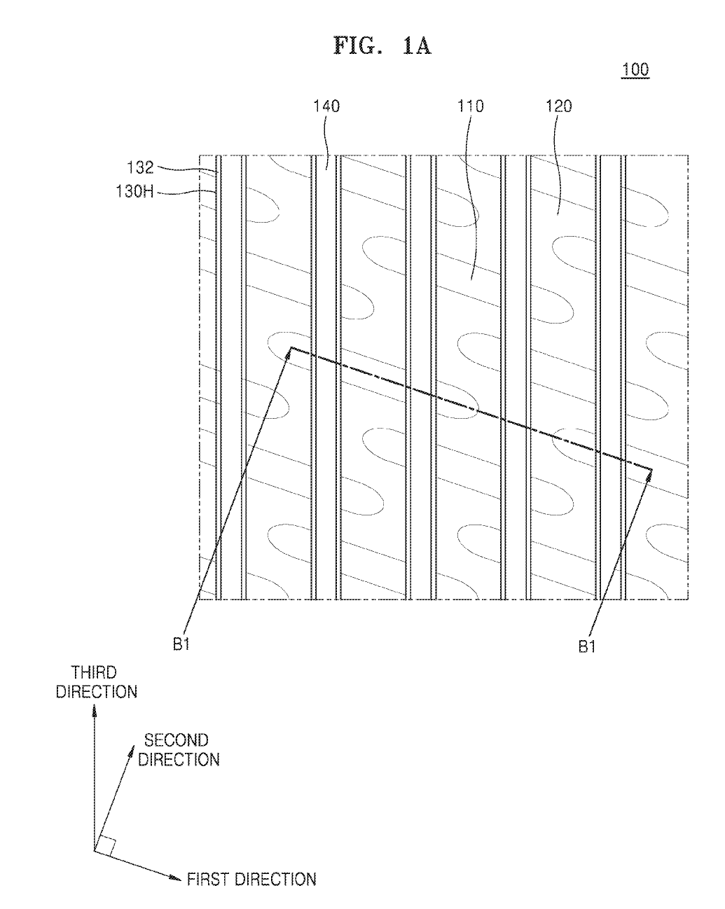

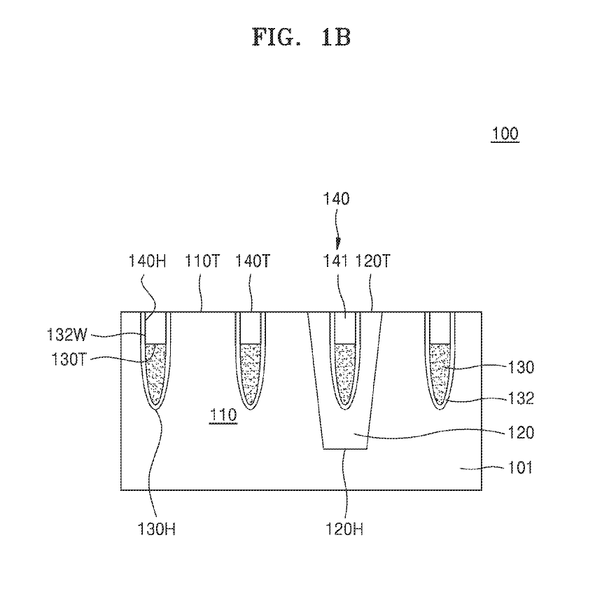

FIG. 1A is a plan view of examples of some elements of a semiconductor device 100 according to an example embodiment, and FIG. 1B is a cross-sectional view taken along a line B1-B1 of FIG. 1A.

Specific shapes and layouts of an active region 110, a device isolation layer 120, a gate dielectric layer 132, and a capping layer 140 shown in FIG. 1A are only examples and may be variously changed within the scope of the inventive concepts.

Referring to FIGS. 1A and 1B, the semiconductor device 100 may include the device isolation layer 120 configured to defining a plurality of active regions 110 in a semiconductor substrate 101, a plurality of word lines 130, the gate dielectric layer 132, and/or the capping layer 140.

The semiconductor substrate 101 may include silicon (Si), for example, crystalline silicon, polycrystalline silicon (poly-Si), or amorphous silicon (a-Si). In some embodiments, the semiconductor substrate 101 may include a semiconductor (e.g., germanium (Ge)) or a compound semiconductor (e.g., silicon germanium (SiGe), silicon carbide (SiC), gallium arsenide (GaAs), indium arsenide (InAs), or indium phosphide (InP)).

Each of the active regions 110 may have a top surface 110T having a major axis positioned in a first direction and a minor axis positioned in a second direction perpendicular to the first direction. That is, the active regions 110, each of which has an isolated island shape, may be repetitively formed apart from one another in the first direction and the second direction.

The device isolation layer 120 may be formed in an isolation trench 120H formed in the semiconductor substrate 101.

In some embodiments, the device isolation layer 120 may be a shallow trench isolation (STI) layer for increasing speed and integration density of the semiconductor device 100.

In some embodiments, the device isolation layer 102 may include at least one of oxides, such as tonen silazene (TOSZ), high temperature oxide (HTO), a high-density plasma (HDP) oxide, tetra ethyl ortho silicate (TEOS), boron-phosphorus silicate glass (BPSG), or undoped silicate glass (USG). Also, the device isolation layer 120 may be an insulating layer including at least one of silicon oxide, silicon nitride, and silicon oxynitride. In some other embodiments, the device isolation layer 120 may have a structure in which a plurality of insulating layers are stacked. For example, the device isolation layer 120 may have a structure in which a first layer (not shown) including silicon nitride and a second layer (not shown) including silicon oxide are stacked.

A plurality of word line trenches 130H, each of which has a line shape extending in a third direction, may be formed in the active regions 110 and the device isolation layer 120 to form recessed channels. The third direction may be a direction that is not perpendicular to the first direction, that is, a direction at an angle to the second direction.

FIG. 1A illustrates that the word line trenches 130H extend in a third direction that is not perpendicular to the first direction, but the inventive concepts are not limited thereto. That is, the word line trenches 130H may extend in a second direction perpendicular to the first direction.

In some embodiments, two word line trenches 130H may be positioned apart from and parallel to each other in each of the active regions 110. Since the word line 130 provided in each of the word line trenches 130H functions as a gate of a transistor (not shown), two transistors may be provided in each of the active regions 110.

The word line 130, the gate dielectric layer 132, and the capping layer 140 may be provided in each of the word line trenches 130H. Thus, the gate dielectric layer 132, the word line 130, and the capping layer 140 may extend in the third direction across the plurality of active regions 110 and the device isolation layer 120.

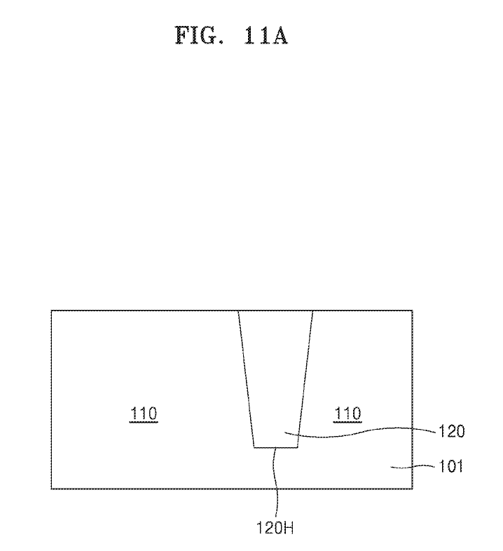

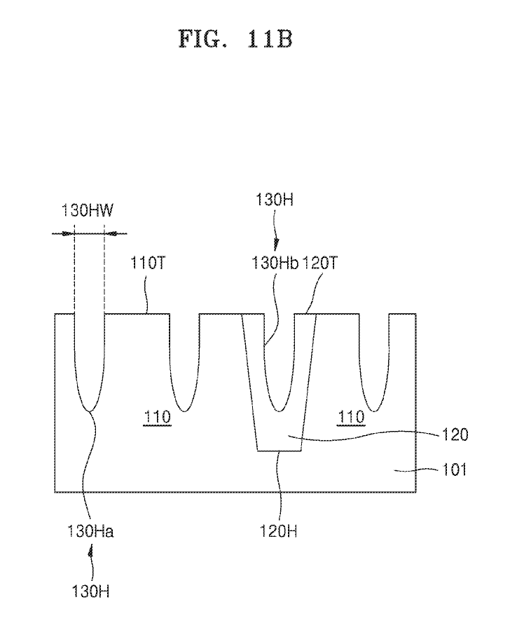

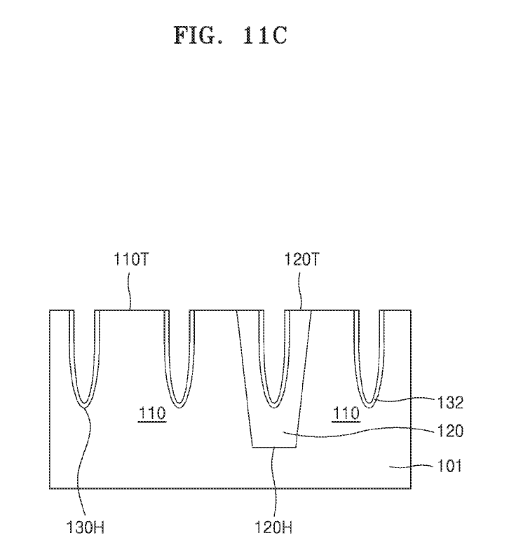

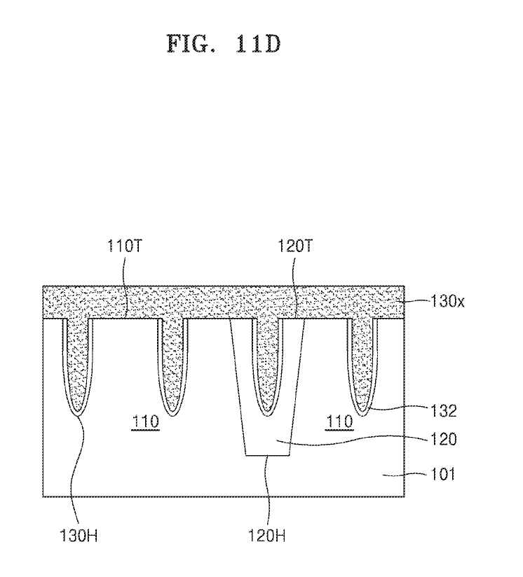

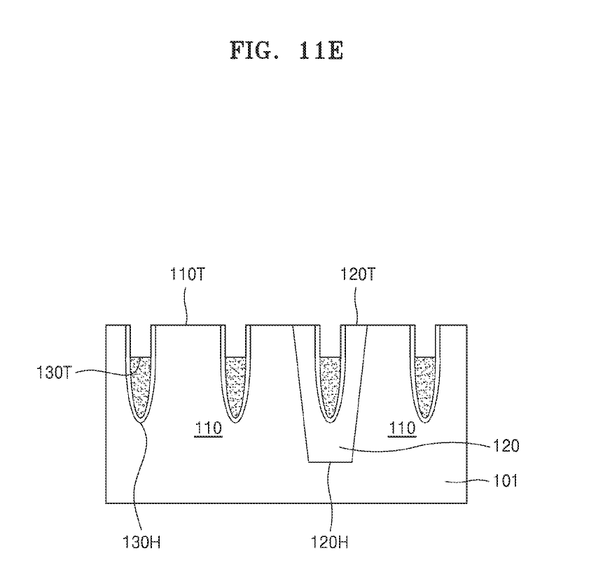

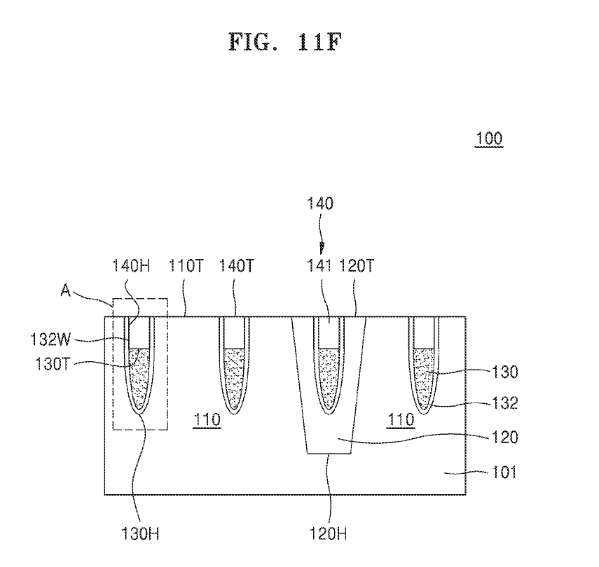

FIG. 1B illustrates a case in which all the word line trenches 130H has the same depth. However, in another case, a word line trench formed in the active region 110 may have a different depth from a word line trench formed in the device isolation layer 120 as will be described in detail later with reference to FIG. 11B.

The word line 130 may be formed in the word line trench 130H. Here, the word line 130 may be formed to fill a portion of each of the word line trenches 130H. Thus, a top surface 130T of the word line 130 may be positioned at a lower level than the top surface 110T of the active regions 110 or a top surface 120T of the device isolation layer 120. When the word line 130 has a buried gate structure, an effective channel length of the semiconductor device 100 may increase to reduce a short channel effect (SCE).

The word lines 130 may include at least one of a doped poly-Si material, a metal material, a metal nitride material, and a metal silicide material. The metal material may be, for example, any one of aluminum (Al), gold (Au), beryllium (Be), bismuth (Bi), cobalt (Co), copper (Cu), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn), and zirconium (Zr) or a combination thereof. The metal nitride material may include, for example, any one of titanium nitride (TiN), tungsten nitride (WN), tantalum nitride (TaN), titanium silicon nitride (TiSiN), tantalum silicon nitride (TaSiN), and tungsten silicon nitride (WSiN), or a combination thereof. The metal silicide material may be, for example, any one of cobalt silicide (CoSiₓ), nickel silicide (NiSiₓ), titanium silicide (TiSiₓ), tungsten silicide (WSiₓ), and tantalum silicide (TaSiₓ), or a combination thereof.

The word line 130 may include a single layer or a compound layer. For example, the word line 130 may include a compound layer formed of a metal material and doped polysilicon (poly-Si). The word line 130 may have a structure with a U-shaped lower section as shown in FIG. 1B, but the inventive concepts are not limited thereto.

The gate dielectric layer 132 may cover an inner wall of each of the word line trenches 130H. Thus, the gate dielectric layer 132 may be interposed between the word lines 130 and the active regions 110 or between the word lines 130 and the device isolation layer 120.

In some embodiments, the gate dielectric layer 132 may include a silicon oxide layer or a high-k dielectric layer. In some other embodiments, the gate dielectric layer 132 may be, for example, a compound layer having a double structure including a silicon oxide layer and a silicon nitride layer or a silicon oxide layer having a nitrided surface. The high-k dielectric layer may include, for example, at least one of aluminum oxide (AlOₓ), tantalum oxide (TaₓO_{y}), titanium oxide (TiOₓ), yttrium oxide (YₓO_{y}), zirconium oxide (ZrOₓ), zirconium silicon oxide (ZrSiₓO_{y}), hafnium oxide (HfOₓ), hafnium silicon oxide (HfSiₓO_{y}), lanthanum oxide (LaₓO_{y}), lanthanum aluminum oxide (LaAlₓO_{y}), lanthanum hafnium oxide (LaHfₓO_{y}), hafnium aluminum oxide (HfAlₓO_{y}), and praseodymium oxide (PrₓO_{y}).

The capping layer 140 may cover the word line 130 and electrically insulate an upper structure (not shown) (e.g., contacts and conductive lines that may be formed in a subsequent process) from the word line 130.

Since the word line 130 has a buried gate structure, the capping layer 140 may be formed in a capping trench 140H, which is defined by the top surface 130T of the word line 130 and a sidewall 132W of the gate dielectric layer 132.

In some embodiments, a top surface 140T of the capping layer 140 may be at substantially the same level as the top surface 110T of the active region 110 and the top surface 120T of the device isolation layer 120.

The capping layer 140 may include at least one stressor 141. The stressor 141 may include, for example, silicon nitride.

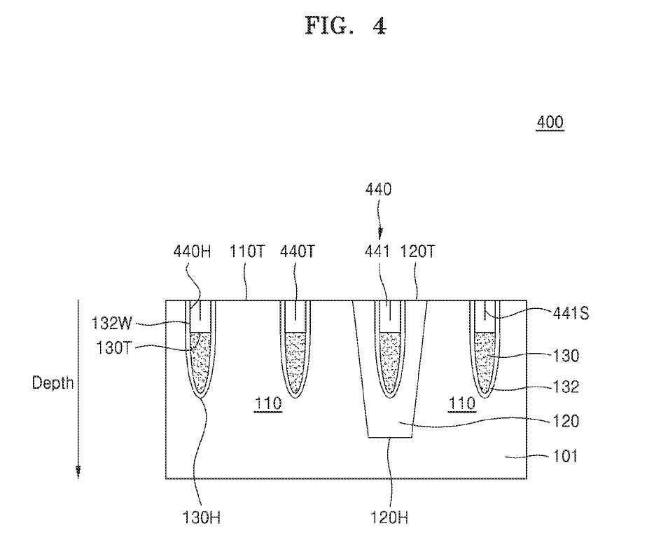

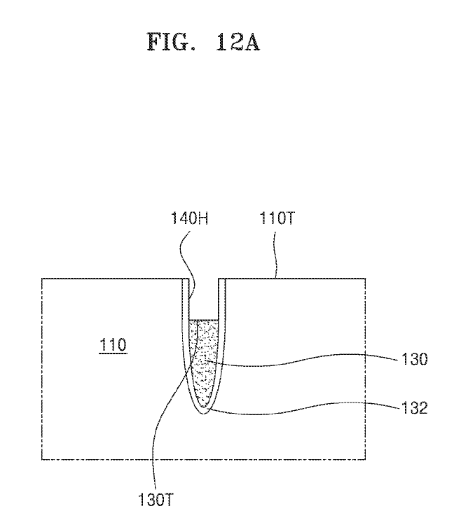

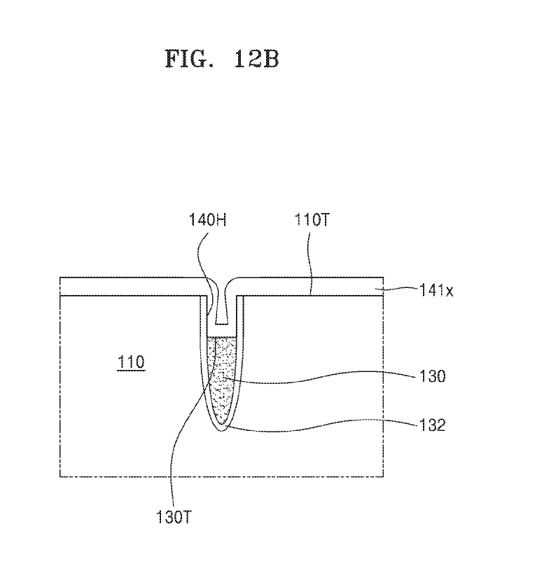

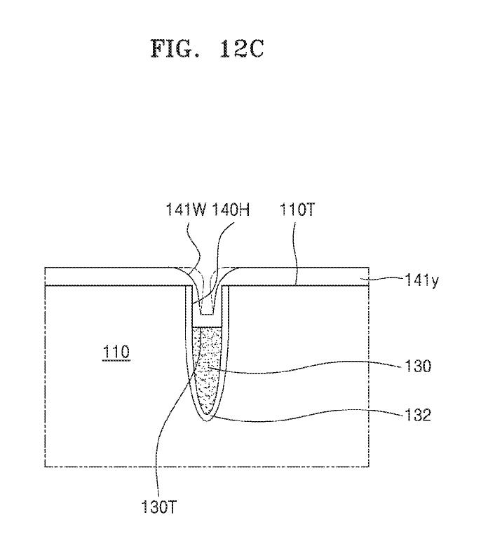

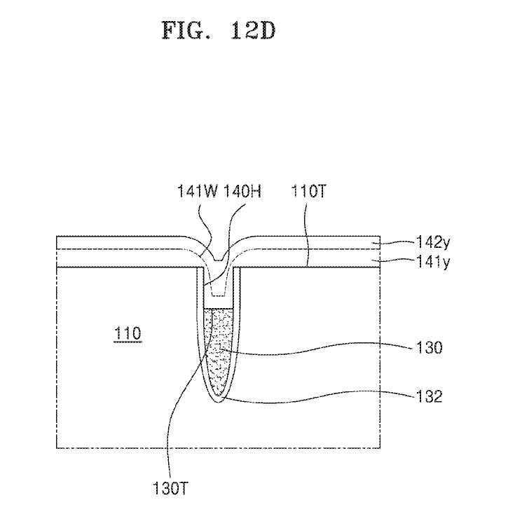

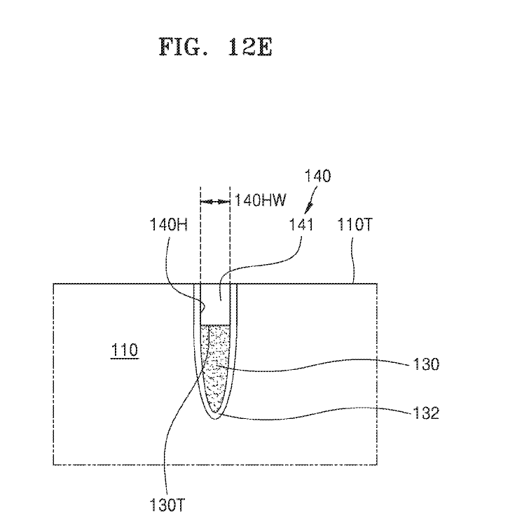

The stressor 141 according to some embodiments may be free from the seam (refer to 441S in FIG. 4) unlike the stressor 442 shown in FIG. 4, which will be described in detail later with reference to FIGS. 12A to 12E.

In some embodiments, the stressor 141 may have a compressive stress. For example, the stressor 141 may have a compressive stress of about 0.1 GPa to 3 GPa. Since the capping layer 140 includes the stressor 141 having the compressive stress, a channel resistance may be reduced so that a drain current may increase.

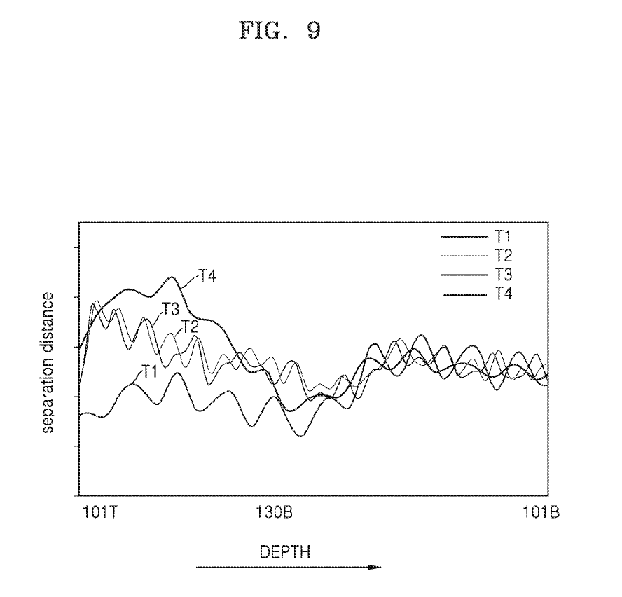

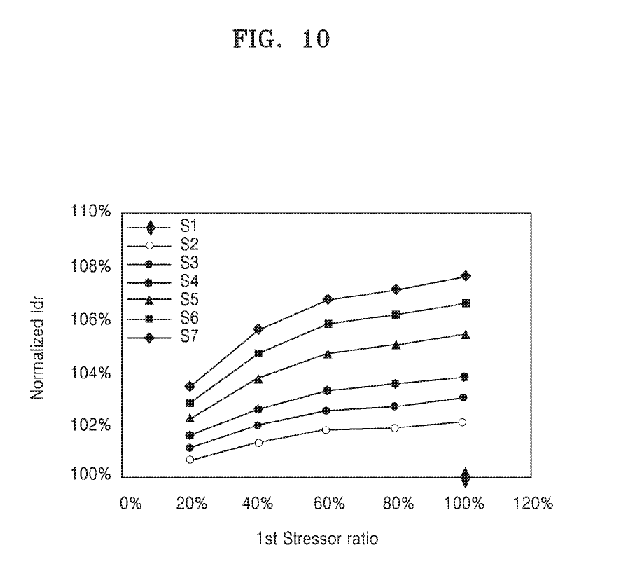

The increase in the drain current due to the stressor 141 will be described in detail later with reference to FIGS. 9 and 10, and a process of forming the stressor 141 will be described in detail later with reference to FIGS. 12A to 12E.

FIGS. 1A and 1B illustrate that word line trench 130H is filled with the word line 130, but the inventive concepts are not limited to thereto. The word line trench 130H may be an address line trench, and the address line trench is filled with an address line.

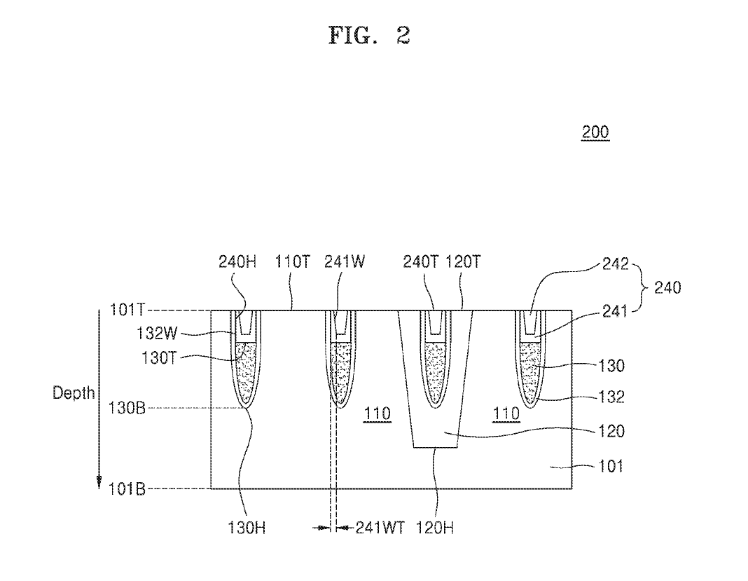

FIG. 2 is a cross-sectional view of examples of some elements of a semiconductor device 200 according to another example embodiment. In FIG. 2, the same reference numerals are used to denote the same elements as in FIGS. 1A and 1B, and repeated descriptions thereof are omitted for brevity.

Referring to FIG. 2, the semiconductor device 200 may include a device isolation layer 120 configured to defining a plurality of active regions 110 in a semiconductor substrate 101, a plurality of word lines 130, a gate dielectric layer 132, and/or a capping layer 240.

The capping layer 240 may be formed in a capping trench 240H and electrically insulate an upper structure (not shown) from the word line 130.

In some embodiments, a top surface 240T of the capping layer 240 may be at substantially the same level as a top surface 110T of the active region 110 and a top surface 120T of the device isolation layer 120.

The capping layer 240 may include a plurality of stressors. For example, the capping layer 240 may include first and second stressors 241 and 242 having different stresses.

The first and second stressors 241 and 242 may include, for example, silicon nitride.

In some embodiments, one of the first and second stressors 241 and 242 may have a compressive stress, while the other thereof may have a tensile stress. For example, the first stressor 241 may have a compressive stress of about 0.1 GPa to about 3 GPs, and the second stressor 242 may have a tensile stress of about 0.1 GPa to about 3 GPa.

In some other embodiments, the first stressor 241 may have a first compressive stress, while the second stressor 242 may have a second compressive stress different from the first compressive stress. For example, the first stressor 241 may have a compressive stress of about 0.1 GPa to about 1.5 GPa, and the second stressor 242 may have a compressive stress of about 1.6 GPa to about 3 GPa.

FIG. 2 illustrates a case in which the first stressor 241 of the capping layer 240 takes a larger percentage of the volume between the top surface 120T of the device isolation layer 120 and the top surface 130T of the word line 130 than the second stressor 242 thereof, but the inventive concepts are not limited thereto. That is, a percentage taken by each of the first and second stressors 241 and 242 in the capping layer 240 may be variously changed as needed.

In some embodiments, a sidewall 241W of the first stressor 241 may be inclined as shown in FIG. 2. That is, a thickness 241WT of the sidewall 241W of the first stressor 241 may increase in a depthwise direction of the semiconductor device 200.

Since the capping layer 240 includes the first and second stressors 241 and 242 having different stresses, a channel resistance may be reduced so that a drain current may increase.

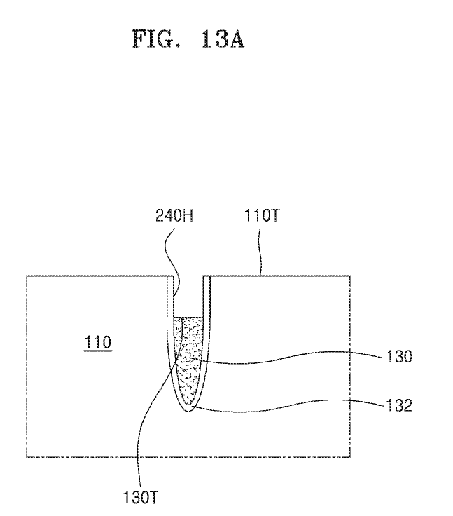

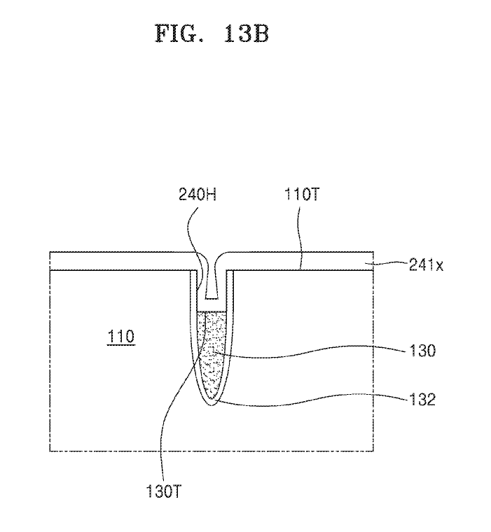

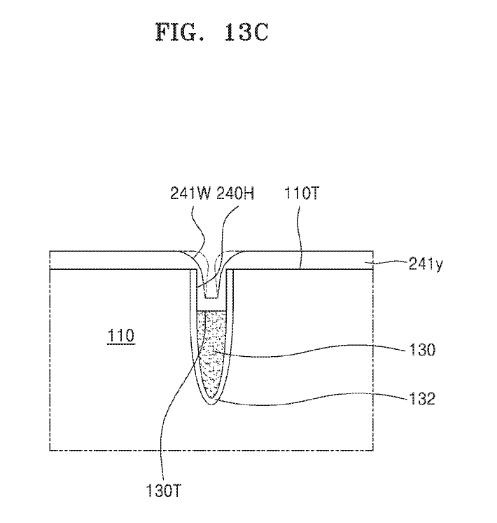

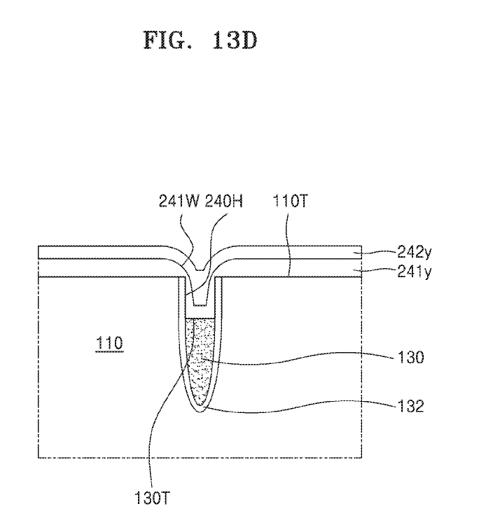

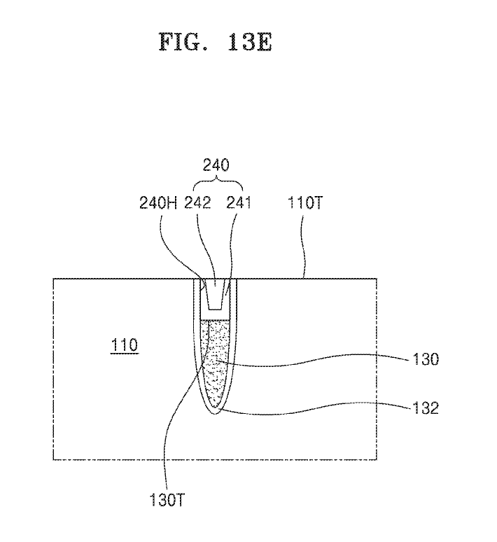

A process of forming the capping layer 240 including the first and second stressors 241 and 242 will be described in detail later with reference to FIGS. 13A to 13E.

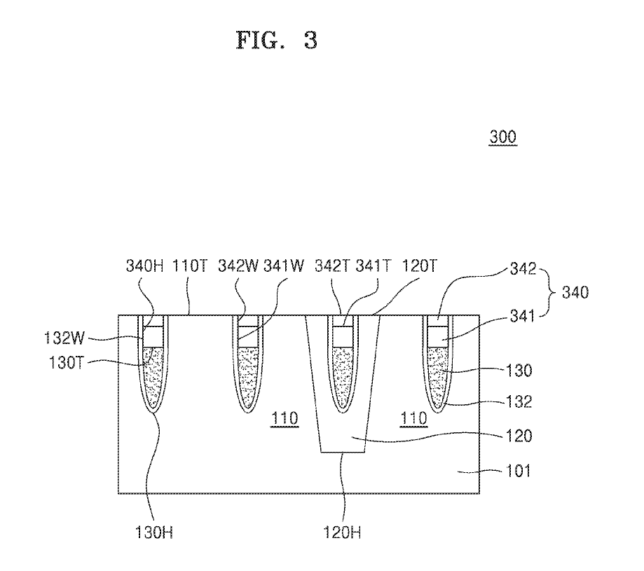

FIG. 3 is a cross-sectional view of examples of some elements of a semiconductor device 300 according to another example embodiment. In FIG. 3, the same reference numerals are used to denote the same elements as in FIGS. 1A to 2, and repeated descriptions thereof are omitted for brevity.

Referring to FIG. 3, the semiconductor device 300 may include a device isolation layer 120 configured to defining a plurality of active regions 110 in a semiconductor substrate 101, a plurality of word lines 130, a gate dielectric layer 132, and/or a capping layer 340.

The capping layer 340 may be formed in a capping trench 340H and electrically insulate an upper structure (not shown) from the word line 130.

The capping layer 340 may include a plurality of stressors. For example, the capping layer 340 may include first and second stressors 341 and 342 having different stresses.

In some embodiments, a sidewall 341W of the first stressor 341 and a sidewall 342W of the second stressor 342 may be in contact with a sidewall 132W of the gate dielectric layer 132.

In some embodiments, a top surface 341T of the first stressor 341 may be substantially parallel to a top surface 342T of the second stressor 342. In this case, the top surface 341T of the first stressor 341T may be at a lower level than a top surface 110T of the active region 110 and a top surface 120T of the device isolation layer 120. The top surface 342T of the second stressor 342 may be at substantially the same level as the top surface 110T of the active region 110 and the top surface 120T of the device isolation layer 120.

The first and second stressors 341 and 342 may include, for example, silicon nitride.

In some embodiments, one of the first and second stressors 341 and 342 may have a compressive stress, while the other thereof may have a tensile stress. In some other embodiments, the first stressor 341 may have a first compressive stress, while the second stressor 342 may have a second compressive stress different from the first compressive stress.

FIG. 3 illustrates a case in which the first stressor 341 of the capping layer 340 takes a larger percentage of the volume between the top surface 120T of the device isolation layer 120 and the top surface 130T of the word line 130 than the second stressor 342 thereof, but the inventive concepts are not limited thereto.

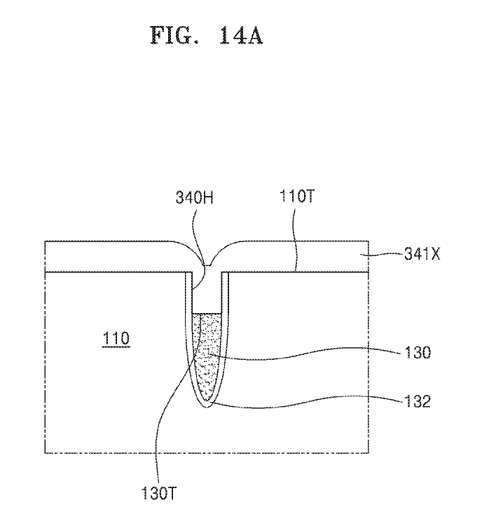

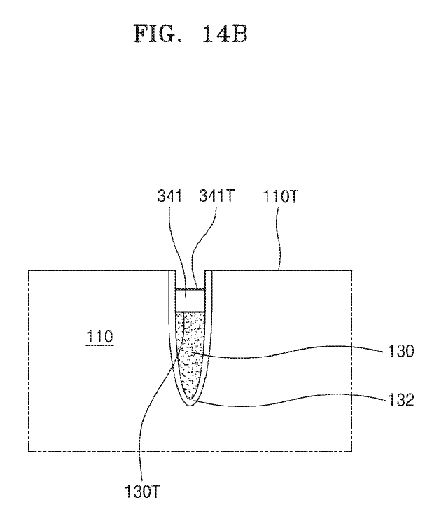

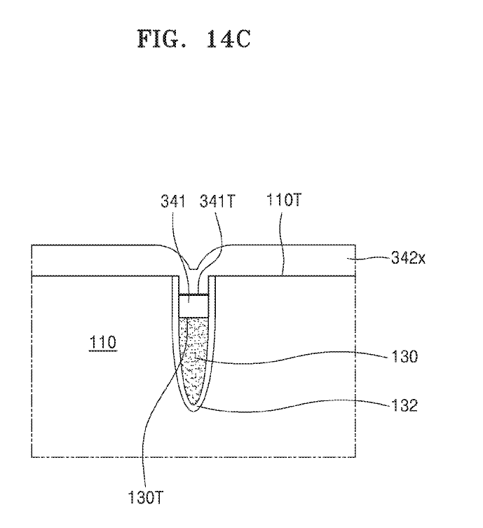

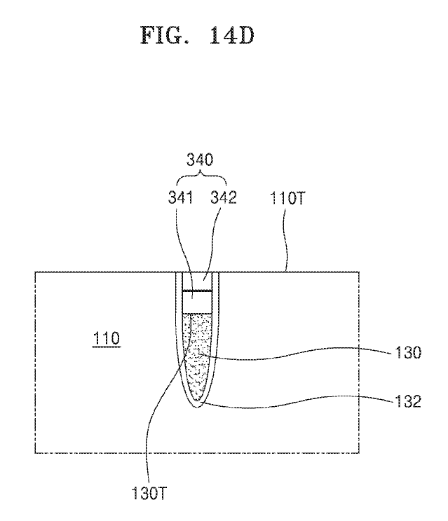

A process of forming the capping layer 340 including the first and second stressors 341 and 342 will be described in detail later with reference to FIGS. 14A to 14D.

FIG. 4 is a cross-sectional view of examples of some elements of a semiconductor device according to another example embodiment. In FIG. 4, the same reference numerals are used to denote the same elements as in FIGS. 1A to 3, and repeated descriptions thereof are omitted for brevity.

Referring to FIG. 4, the semiconductor device 400 may include a device isolation layer 120 configured to defining a plurality of active regions 110 in a semiconductor substrate 101, a plurality of word lines 130, a gate dielectric layer 132, and/or a capping layer 440.

The capping layer 440 may be formed in a capping trench 440H and electrically insulate an upper structure (not shown) from the word line 130.

In some embodiments, a top surface 440T of the capping layer 440 may be at substantially the same level as a top surface 110T of the active region 110 and a top surface 120T of the device isolation layer 120.

The capping layer 440 may include at least one stressor 441. The stressor 441 may include, for example, silicon nitride.

The stressor 441 may have a compressive stress. For example, the stressor 441 may have a compressive stress of about 0.1 GPa to 3 GPa.

The stressor 441 may have a seam 441S having a line shape, which tends to be vertical in a cross-sectional view. In some embodiments, the seam 441S may extend in a direction parallel to a depthwise direction of the semiconductor device 400.

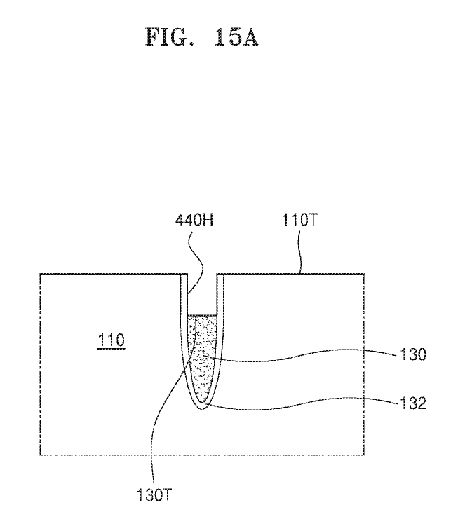

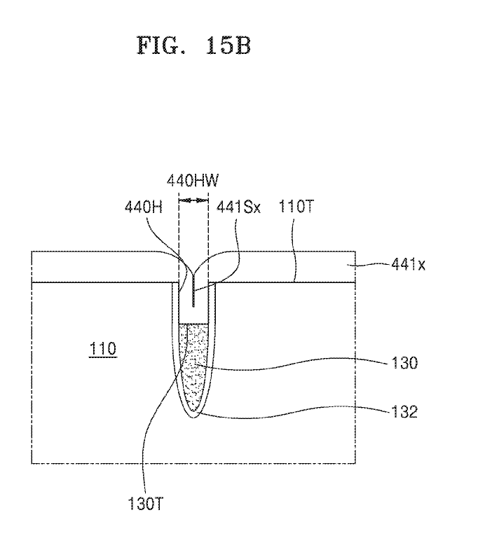

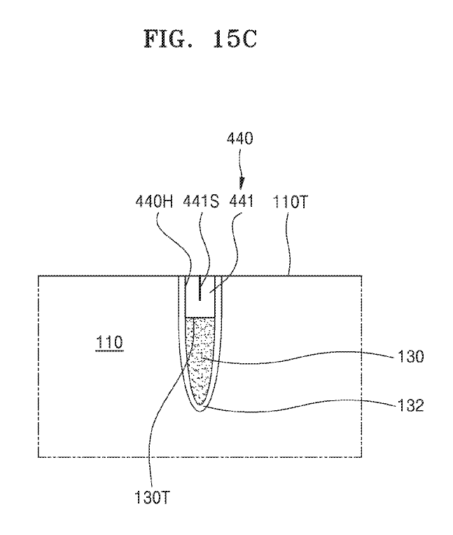

A process of forming the capping layer 440 including the stressor 441 will be described in detail later with reference to FIGS. 15A to 15C.

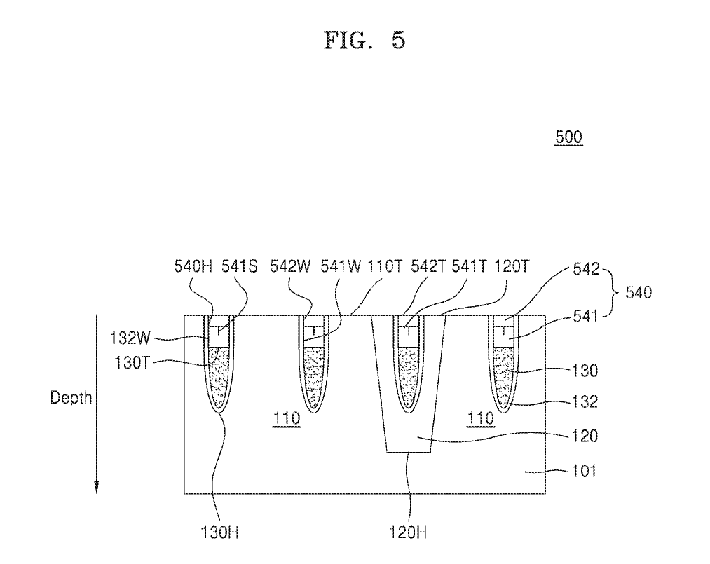

FIG. 5 is a cross-sectional view of examples of some elements of a semiconductor device 500 according to another example embodiment. In FIG. 5, the same reference numerals are used to denote the same elements as in FIGS. 1A to 4, and repeated descriptions thereof are omitted for brevity.

Referring to FIG. 5, the semiconductor device 500 may include a device isolation layer 120 configured to defining a plurality of active regions 110 in a semiconductor substrate 101, a plurality of word lines 130, a gate dielectric layer 132, and/or a capping layer 540.

The capping layer 540 may be formed in a capping trench 540H and electrically insulate an upper structure (not shown) from the word line 130.

The capping layer 540 may include a plurality of stressors. For example, the capping layer 540 may include first and second stressors 541 and 542 having different stresses. The first and second stressors 541 and 542 may include, for example, silicon nitride.

The first stressor 541 may have a seam 541S having a line shape, which tends to be vertical in a cross-sectional view. In some embodiments, the seam 541S may extend in a direction parallel to a depthwise direction of the semiconductor device 500.

In some embodiments, one of the first and second stressors 541 and 542 may have a compressive stress, while the other thereof may have a tensile stress. In some other embodiments, the first stressor 541 may have a first compressive stress, while the second stressor 542 may have a second compressive stress different from the first compressive stress.

FIG. 5 illustrates a case in which the first stressor 541 of the capping layer 540 takes a larger percentage of the volume between the top surface 120T of the device isolation layer 120 and the top surface 130T of the word line 130 than the second stressor 542 thereof, but the inventive concepts are not limited thereto.

In some embodiments, a sidewall 541W of the first stressor 541 and a sidewall 542W of the second stressor 542 may be in contact with a sidewall 132W of the gate dielectric layer 132.

A top surface 541T of the first stressor 541 may be substantially parallel to a top surface 542T of the second stressor 542.

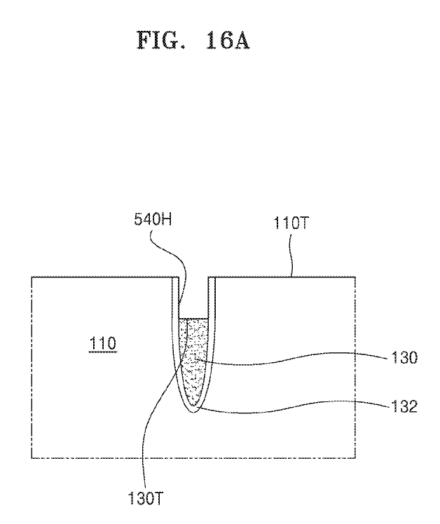

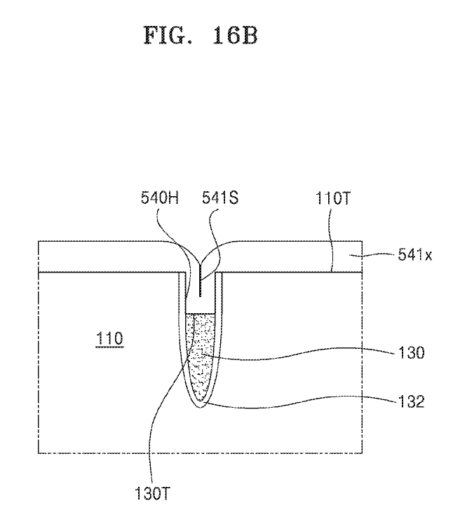

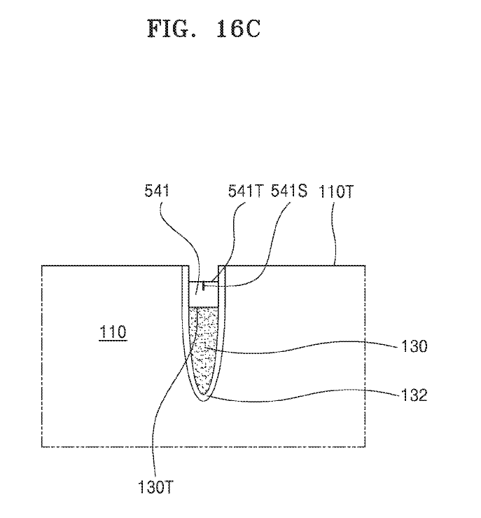

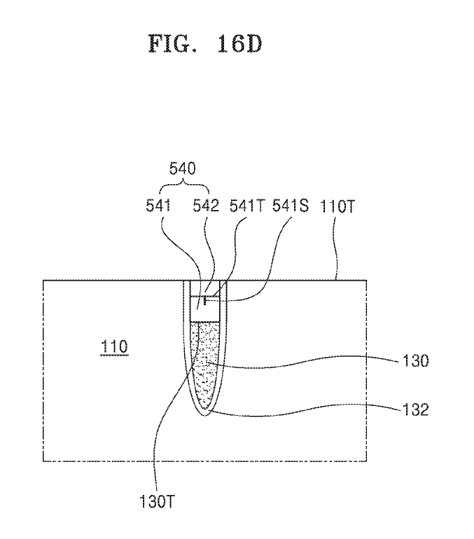

A process of forming the capping layer 540 including the first and second stressors 541 and 542 will be described in detail later with reference to FIGS. 16A to 16D.

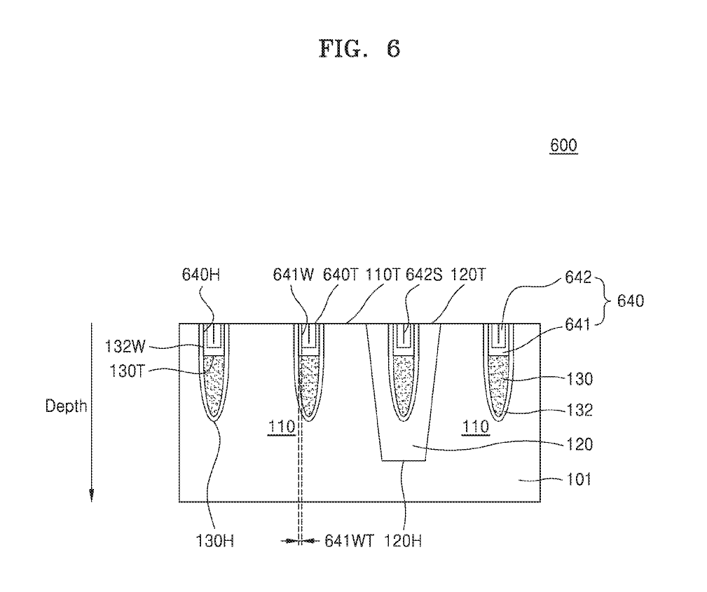

FIG. 6 is a cross-sectional view of examples of some elements of a semiconductor device 600 according to another example embodiment. In FIG. 6, the same reference numerals are used to denote the same elements as in FIGS. 1A to 5, and repeated descriptions thereof are omitted for brevity.

Referring to FIG. 6, the semiconductor device 600 may include a device isolation layer 120 configured to defining a plurality of active regions 110 in a semiconductor substrate 101, a plurality of word lines 130, a gate dielectric layer 132, and/or a capping layer 640.

The capping layer 640 may be formed in a capping trench 640H and electrically insulate an upper structure (not shown) from the word line 130.

In some embodiments, a top surface 640T of the capping layer 640 may be at substantially the same level as a top surface 110T of the active region 110 and a top surface 120T of the device isolation layer 120.

The capping layer 640 may include a plurality of stressors. For example, the capping layer 640 may include first and second stressors 641 and 642 having different stresses. The first and second stressors 641 and 642 may include, for example, silicon nitride.

In some embodiments, one of the first and second stressors 641 and 642 may have a compressive stress, while the other thereof may have a tensile stress. In some other embodiments, the first stressor 641 may have a first compressive stress, while the second stressor 642 may have a second compressive stress different from the first compressive stress.

FIG. 6 illustrates a case in which the first stressor 641 of the capping layer 640 takes a larger percentage of the volume between the top surface 120T of the device isolation layer 120 and the top surface 130T of the word line 130 than the second stressor 642 thereof, but the inventive concepts are not limited thereto.

In some embodiments, a sidewall 641W of the first stressor 641 may extend in a direction parallel to a depthwise direction of the semiconductor device 600. That is, the first stressor 641 may be conformally formed within the capping trench 640H. Thus, the sidewall 641W of the first stressor 641 may have a substantially constant thickness 641WT along the depthwise direction of the semiconductor device 600.

In some embodiments, the second stressor 642 may have a seam 642S having a line shape, which tends to be vertical in a cross-sectional view. The seam 642S may extend in a direction parallel to a depthwise direction of the semiconductor device 600.

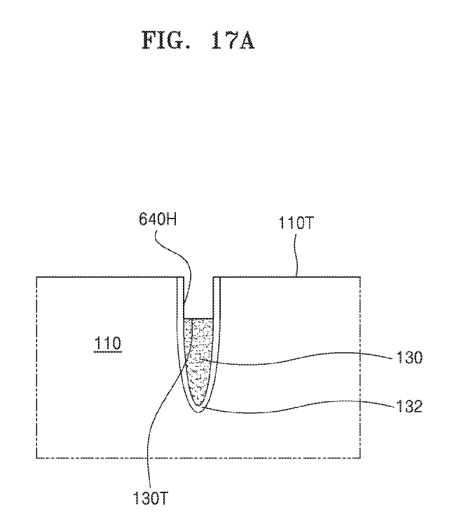

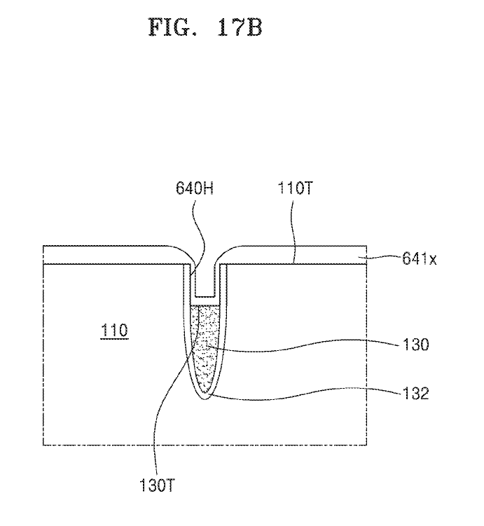

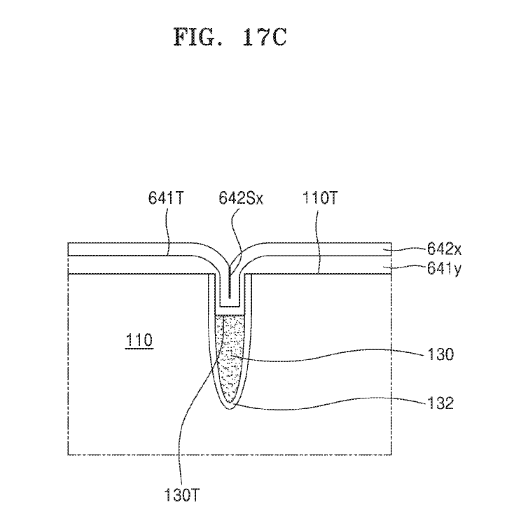

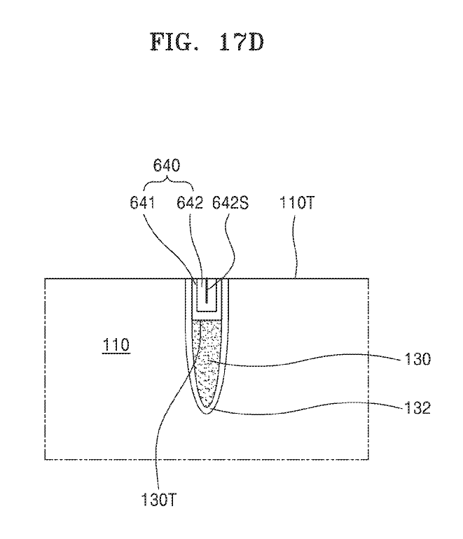

A process of forming the capping layer 640 including the first and second stressors 641 and 642 will be described in detail later with reference to FIGS. 17A to 17D.

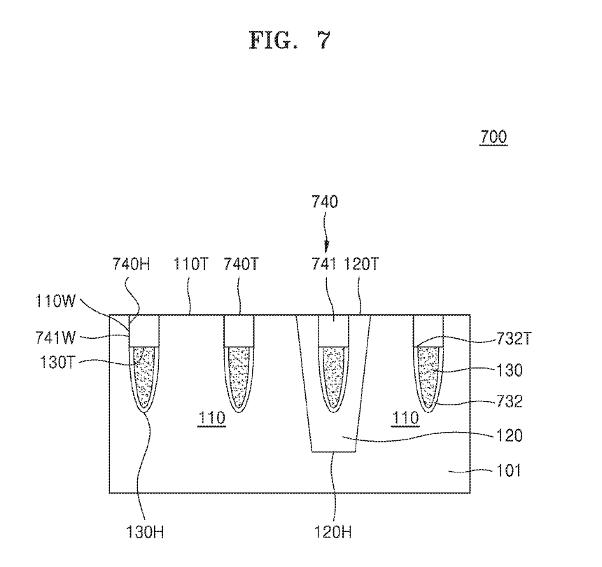

FIG. 7 is a cross-sectional view of examples of some elements of a semiconductor device 700 according to another example embodiment. In FIG. 7, the same reference numerals are used to denote the same elements as in FIGS. 1A to 6, and repeated descriptions thereof are omitted for brevity.

Referring to FIG. 7, the semiconductor device 700 may include a device isolation layer 120 configured to defining a plurality of active regions 110 in a semiconductor substrate 101, a plurality of word lines 130, a gate dielectric layer 732, and/or a capping layer 740.

The gate dielectric layer 732 may cover a portion of an inner wall of each of the word line trenches 130H.

In some embodiments, as shown in FIG. 7, the gate dielectric layer 732 may be interposed only between the word line 130 and the active region 110 or between the word line 130 and the device isolation layer 120 but may not be interposed between the capping layer 740 and the active region 110 or between the capping layer 740 and the device isolation layer 120. In this case, a top surface 130T of the word line 130 may be positioned at substantially the same level as a top surface 732T of the gate dielectric layer 732.

In some embodiments, the gate dielectric layer 732 may be formed of a similar material to that of the gate dielectric layer 132 described with reference to FIGS. 1A and 1B, and descriptions thereof will be omitted.

The capping layer 740 may be formed in a capping trench 740H and electrically insulate an upper structure (not shown) from the word line 130.

In some embodiments, a top surface 740T of the capping layer 740 may be at substantially the same level as a top surface 110T of the active region 110 and a top surface 120T of the device isolation layer 120.

The capping layer 740 may include at least one stressor 741. The stressor 741 may include, for example, silicon nitride.

In some embodiments, a sidewall 741W of the stressor 741 may be in contact with a sidewall 110W of the active region 110.

The present embodiment illustrates an example in which the capping layer 740 includes only one stressor 741, but the inventive concepts are not limited thereto. For example, the capping layer 740 may include a plurality of stressors like the capping layers 240, 340, 540, and 640 described with reference to FIGS. 2, 3, 5, and 6.

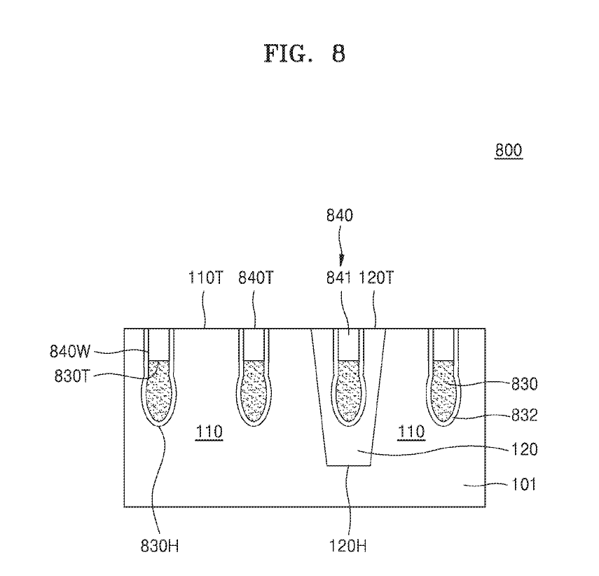

FIG. 8 is a cross-sectional view of examples of some elements of a semiconductor device 800 according to another example embodiment. In FIG. 8, the same reference numerals are used to denote the same elements as in FIGS. 1A to 7, and repeated descriptions thereof are omitted for brevity.

Referring to FIG. 8, the semiconductor device 800 may include a device isolation layer 120 configured to defining a plurality of active regions 110 in a semiconductor substrate 101, a plurality of word lines 830, a gate dielectric layer 832, and/or a capping layer 840.

A plurality of word line trenches 830H for forming recessed channels may be formed in the active regions 110 and the device isolation layer 120.

In some embodiments, two word line trenches 830H may be positioned apart from and parallel to each other in each of the active regions 110. Since the word line 830 provided in each of the word line trenches 830H functions as a gate of a transistor (not shown), two transistors may be provided in each of the active regions 110.

The word line 830, the gate dielectric layer 832, and the capping layer 840 may be provided in each of the word line trenches 830H.

FIG. 8 illustrates a case in which all the word line trenches 830H have the same depth. However, in another case, a word line trench formed in the active region 110 may have a different depth from a word line trench formed in the device isolation layer 120.

The word line 830 may be formed to fill a portion of each of the word line trenches 830H. Thus, a top surface 830T of the word line 830 may be positioned at a lower level than the top surface 110T of the active regions 110 or a top surface 120T of the device isolation layer 120.

The word line 830 according to some embodiments may have a bulb-type structure having a roughly circular lower section. When the word line 830 has the bulb-type structure, the word line 830 may be formed in the semiconductor substrate 101 to increase an effective channel length of the semiconductor device 800 so that an SCE may be reduced. Also, since the word line 830 has the circular lower section, a dopant concentration of the semiconductor substrate 101 may be reduced, and drain-induced barrier lowering (DIBL) may be improved.

The word line 830 may include at least one of a doped poly-Si material, a metal material, a metal nitride material, and a metal silicide material. A detailed description of materials of the word line 830 is the same as that of the word line 130 of FIGS. 1A and 1B.

The gate dielectric layer 832 may cover an inner wall of each of the word line trenches 830H. That is, the gate dielectric layer 832 may be interposed between the word lines 830 and the active regions 110 or the word lines 830 and the device isolation layer 120.

In some embodiments, the gate dielectric layer 832 may be formed of a similar material to that of the gate dielectric layer 132 described with reference to FIGS. 1A and 1B, and descriptions thereof will be omitted.

The capping layer 840 may be formed in a capping trench 840H and electrically insulate an upper structure (not shown) from the word lines 830.

In some embodiments, a top surface 840T of the capping layer 840 may be at substantially the same level as a top surface 110T of the active region 110 and a top surface 120T of the device isolation layer 120.

The capping layer 840 may include at least one stressor 841. The stressor 841 may include, for example, silicon nitride.

The stressor 841 may have a compressive stress. For example, the stressor 841 may have a compressive stress of about 0.1 GPa to 3 GPa.

The present embodiment illustrates an example in which the capping layer 840 includes only one stressor 841, but the inventive concepts are not limited thereto. For example, the capping layer 840 may include a plurality of stressors like the capping layers 240, 340, 540, and 640 described with reference to FIGS. 2, 3, 5, and 6.

FIGS. 9 and 10 are graph showing improvements in current characteristics of a semiconductor device according to example embodiments.

FIG. 9 shows a relative separation distance between silicon lattices relative to a depth of a semiconductor device from a top surface 101T of a semiconductor substrate 101 to a bottom surface 101B thereof. The graph of FIG. 9 will be described with cross-reference to some elements of the semiconductor device 200 shown in FIG. 2.

In the present embodiment, a term “ratio” may refer to a volume ratio.

Curve “T1” may show a case in which the capping layer 240 of the semiconductor device 200 does not include a stressor having a compressive stress. In other words, curve “Ti” may show a case in which the entire capping layer 240 of the semiconductor device 200 has a tensile stress.

Curve “T2” may show a case in which the capping layer 240 includes a stressor having a compressive stress in a ratio of about 33%. For example, curve “T2” may show a case in which the first stressor 241 having a compressive stress takes up to about 33% of the capping layer 240 and the second stressor 242 having a tensile stress takes up to the remaining ratio of the capping layer 240.

Curve “T3” may show a case in which the capping layer 240 includes a stressor having a compressive stress in a ratio of about 66%. For example, curve “T3” may show a case in which the first stressor 241 having a compressive stress takes up to about 66% of the capping layer 240 and the second stressor 242 having a tensile stress takes up to the remaining ratio of the capping layer 240.

Curve “T4” may show a case in which the capping layer 240 includes a stressor having a compressive stress in a ratio of about 88%. For example, curve “T4” may show a case in which the first stressor 241 having a compressive stress takes up to about 88% of the capping layer 240, and the second stressor 242 having a tensile stress takes up to the remaining ratio of the capping layer 240.

From the result of FIG. 9, it can be confirmed that as a ratio of the stressor having a compressive stress in the capping layer 240 increases, a separation distance between silicon lattices increases. This result may be conspicuously obtained in a region that may be substantially related to a resistance of a channel region, namely, a region between the top surface 101T of the semiconductor substrate 101 to the bottom surface 130B of the word line 130.

Therefore, as the separation distance between the silicon lattices increases, the migration of electrons may become brisk, and a drain current may increase.

FIG. 10 shows normalized drain current (Idr) characteristics relative to a first stressor ratio in which the first stressor (refer to 241 in FIG. 2) is included in the capping layer 240. The graph of FIG. 10 will be described with cross-reference to some elements of the semiconductor device 200 shown in FIG. 2.

In example embodiments, a term “ratio” may refer to a volume ratio.

In curves “S1” to “S7”, the second stressor 242 may have a tensile stress of about 1.2 GPa, while the first stressor 241 may have different stresses.

Curve “S1” shows a case in which the first stressor 241 has a tensile stress of about 1.2 GPa.

Curve “S2” shows a case in which the first stressor 241 has a tensile stress of about 0.6 GPa.

Curve “S3” shows a case in which the first stressor 241 has a tensile stress of about 0.3 GPa.

Curve “S4” shows a case in which the first stressor 241 has a stress of about 0 GPa.

Curve “S5” shows a case in which the first stressor 241 has a compressive stress of about 0.6 GPa.

Curve “S6” shows a case in which the first stressor 241 has a compressive stress of about 1.2 GPa.

Curve “S7” shows a case in which the first stressor 241 has a compressive stress of about 1.8 GPa.

From the result of FIG. 10, it can be confirmed that in each of curves “S2” to “S7”, as a ratio of the first stressor 241 increases, normalized drain current characteristics are improved. Curve “S1” is irrelevant here because the first stressor 241 has the same stress as the second stressor 242.

That is, as a ratio of the first stressor 241 having a smaller tensile stressor than the second stressor 242 (e.g., “S2” to “S4”) or having a compressive stress (e.g., “S5” to “S7”) increases, a separation distance between silicon lattices may increase (refer to FIG. 9) so that normalized drain current characteristics may be improved.

When the results of curves “S1” to “S7” are compared in a case in which the first stressor (refer to 241 in FIG. 2) is included in the same ratio, it can be confirmed that as a tensile stress of the first stressor 241 decreases (i.e., a compressive stress of the first stressor 241 increases), normalized drain current characteristics are improved.

FIGS. 11A to 11F are cross-sectional views of process operations of a method of manufacturing a semiconductor device 100 according to an example embodiment. In FIGS. 11A to 11F, the same reference numerals are used to denote the same elements as in FIGS. 1A to 10, and repeated descriptions thereof are omitted for brevity.

Referring to FIG. 11A, a process of forming a device isolation layer 120 may be performed on a semiconductor substrate 101. A well (not shown) may be formed in the semiconductor substrate 101. That is, a p-well may be formed by implanting p-type impurities into an n NMOS region, while an n-well may be formed by implanting n-type impurities into a PMOS region. Optionally, an ion implantation process for improving threshold voltage characteristics of the semiconductor device 100 may be performed on an active region 110 defined by the device isolation layer 120.

The formation of the device isolation layer 120 may include forming a device isolation trench 120H by using an etching process and depositing an insulating material. The process of forming the device isolation trench 120H may be, for example, an STI process.

After the insulating material is deposited, a planarization process (e.g., a chemical mechanical polishing (CMP) process) may be performed to form a buried device isolation layer 120.

Referring to FIG. 11B, a plurality of word line trenches 130H may be formed in a semiconductor substrate 101 in which an active region 110 and a device isolation layer 120 are formed.

Each of the word line trenches 130H may be formed to have a width 130HW of, for example, about 10 nm to about 200 nm, for example, about 50 nm or less. When a subsequent process is finished, a recessed channel region may be formed in the semiconductor substrate 101 near the word line trench 130H.

In some embodiments, the word line trenches 130H may be formed by etching portions of a top surface 110T of the active region 110 and portions of a top surface 120T of the device isolation layer 120. An etching process for forming the word line trenches 130H may be, for example, any one of a physical etching process (e.g., a sputter etching process), a chemical etching process (e.g., a reactive radical etching process), and a chemicophysical etching process (e.g., a reactive ion etching (RIE) process, a magnetically enhanced RIE (MERIE) process, a transformer coupled plasma (TCP) etching process, and an inductively coupled plasma (ICP) etching process).

Although not shown, to form the word line trenches 130H, a buffer insulating layer (not shown) including, for example, silicon oxide may be formed on the top surface 110T of the active region 110 and the top surface 120T of the device isolation layer 120.

FIG. 11B illustrates a case in which all the word line trenches 130H have the same depth. However, in another case, a word line trench 130Ha formed in the active region 110 may have a different depth from a word line trench 130Hb formed in the device isolation layer 120.

For example, the word line trench 130Hb formed in the device isolation layer 120 may be formed to have a greater depth than the word line trench 130Ha formed in the active region 110.

Since the active region 110 includes a silicon material and the device isolation layer 120 includes oxide, the active region 110 may have an etch selectivity with respect to the device isolation layer 120.

Referring to FIG. 11C, a gate dielectric layer 132 may be formed to cover an inner wall of each of the word line trenches 130H.

The gate dielectric layer 132 may be formed by using various methods, for example, a thermal oxidation process, a rapid thermal oxidation (RTO) process, a chemical vapor deposition (CVD) process, a plasma-enhanced CVD (PECVD) process, a high-density plasma CVD (HDP CVD) process, a digital CVD process, an ICP CVD process, a capacitor-coupled plasma CVD (CCP CVD) process, a pulsed CVD process, an atomic layer deposition (ALD) process, or a sputtering process.

In some embodiments, the formation of the gate dielectric layer 132 may include forming a dielectric layer (not shown) to cover the top surface 110T of the active region 110, the top surface 120T of the device isolation layer 120, and the word line trenches 130H and removing the dielectric layer from the top surface 110T of the active region 110 and the top surface 120T of the device isolation layer 120.

As described above with reference to FIGS. 1A and 1B, the gate dielectric layer 132 may include a silicon oxide layer or a high-k dielectric layer, a compound layer having a double structure including a silicon oxide layer and a silicon nitride layer, or a silicon oxide layer having a nitrided surface.

The silicon oxide layer having the nitrided surface may be formed by using various methods, for example, a rapid thermal annealing (RTA) process using a nitrogen-containing gas (e.g., NH3 gas), a spike RTA process, a milisecond RTA process, a laser RTA process, a plasma nitridation process, a plasma ion implantation process, a PECVD process, an HDP CVD process, or a radical nitridation process. Alternatively, the formation of the silicon oxide layer having the nitrided surface may include performing a nitridation process and performing an annealing process in an inactive atmosphere containing an inactive gas, such as helium (He) or argon (Ar).

Referring to FIG. 11D, a conductive layer 130x may be formed to cover the top surface 110T of the active region 110, the top surface 120T of the device isolation layer 120, and the gate dielectric layer 132.

The conductive layer 130x may be formed by using, for example, a CVD process, a PECVD process, a HDP-CVD process, a sputtering process, or an ALD process.

The conductive layer 130x may include at least one of a doped poly-Si material, a metal material, a metal nitride material, and a metal silicide material. Since the metal material, metal nitride material, and the metal silicide material are described with reference to FIG. 1B, descriptions thereof are omitted here.

Referring to FIG. 11E, the conductive layer 130x may be etched back to form a word line 130.

The word line 130 may be completely buried in the semiconductor substrate 101 due to a polishing process. That is, a top surface 130T of the word line 130 may be positioned at a lower level than a top surface 110T of the active regions 110 or a top surface 120T of the device isolation layer 120.

Referring to FIG. 11F, a capping layer 140 including a stressor 141 may be formed to cover the word line 130, thereby completing the manufacture of the semiconductor device 100. Hereinafter, a process of forming the capping layer 140 according to an example embodiment will now be described in detail with reference to FIGS. 12A to 12E.

FIGS. 12A to 12E are cross-sectional views of process operations of a method of manufacturing a capping layer 140 according to an example embodiment. In FIGS. 12A to 12E, the same reference numerals are used to denote the same elements as in FIGS. 1A to 11F, and repeated descriptions thereof are omitted for brevity.

FIGS. 12A to 12E show sectional structures corresponding to an enlarged view of a region A of FIG. 11F.

Referring to FIG. 12A, a word line 130 may be buried in a semiconductor substrate 101 as described above with reference to FIG. 11E. Since a top surface 130T of the word line 130 is positioned at a lower level than a top surface 110T of an active region 110 or a top surface 120T of a device isolation layer 120, a capping trench 140H may be defined.

Referring to FIG. 12B, a first stressor layer 141x may be formed to cover the top surface 110T of the active region 110 and the capping trench 140H.

In some embodiments, the first stressor layer 141x may be formed by using a plasma source. Specifically, the first stressor layer 141x may be formed by using, for example, at least one of a PECVD process, an HDP CVD process, an ICP CVD process, and a CCP CVD process.

In some embodiments, the process of forming the first stressor layer 141x may be performed at a temperature of, for example, about 300° C. to about 700° C.

In some embodiments, a gas used in the process of forming the first stressor layer 141x may include, for example, at least one of SIH₄ gas, N₂ gas, and NH₃ gas.

When the first stressor layer 141x is formed by using the plasma source, a stress of the first stressor layer 141x may be controlled. Thus, the first stressor layer 141x may have a compressive stress of about 0.1 GPa to about 3 GPa.

In some embodiments, the stress of the first stressor layer 141x may be controlled by adjusting a content ratio of silicon to nitrogen (Si:N) in the gas. In some other embodiments, the stress of the first stressor layer 141x may be controlled by adjusting a density of the plasma source.

Referring to FIG. 12C, the first stressor layer 141x may be partially etched to form a first stressor layer 141y. The etching process may be, for example, any one of a physical etching process (e.g., a sputter etching process), a chemical etching process (e.g., a reactive radical etching process), and a chemicophysical etching process (e.g., an RIE process, an MERLE process, a TCP etching process, and an ICP etching process).

A sidewall 141W of the first stressor layer 141y positioned in the vicinity of the capping trench 140H may be inclined due to the etching process.

Referring to FIG. 12D, a second stressor 142y may be formed on the first stressor layer 141y. The second stressor layer 142y may be formed by using a similar process to the process of forming the first stressor layer 141x described with reference to FIG. 12B.

In some embodiments, the second stressor layer 142y may have substantially the same stress as the first stressor layer 141y. A content ratio of silicon to nitrogen in a gas source used in a process of forming the second stressor layer 142y and a density of a plasma source may be the same as in a process of forming the first stressor layer 141y so that the first stressor layer 141y may have substantially the same stress as the second stressor layer 142y.

Example embodiments describe a case in which only the first and second stressor layers 141y and 142y are formed to fill the capping trench 140H, a larger number of stressor layers than the first and second stressor layers 141y and 142y may be formed to fill the capping trench 140H. That is, the process of forming the stressor layer as described in FIG. 12B and the process of etching the stressor layer as described in FIG. 12C may be repeated a plurality of times.

Referring to FIG. 12E, the first and second stressor layers 141y and 142y may be polished until the top surface 110T of the active region 110 is exposed, thereby forming a capping layer 140 including a stressor 141.

Thus, by repeating the process of forming the stressor layer and the etching process, even if the capping trench 140H has a fine width 140HW, a high-quality stressor 141 may be formed. Due to the above-described processes, the stressor 141 may be free from the seam (refer to 441S in FIG. 4), unlike the stressor 442 shown in FIG. 4.

FIGS. 13A to 13E are cross-sectional view of process operations of a method of manufacturing the capping layer 240 (refer to FIG. 2) according to another example embodiment. In FIGS. 13A to 13E, the same reference numerals are used to denote the same elements as in FIGS. 1A to 12E, and repeated descriptions thereof are omitted for brevity.

Referring to FIG. 13A, similar to that described above with reference to FIG. 11E, a semiconductor substrate 101 in which a word line 130 is buried may be prepared. A top surface 130T of the word line 130 may be located at a lower level than a top surface 110T of an active region 110 or a top surface 120T of a device isolation layer 120 so that a capping trench 240H may be defined.

Referring to FIG. 13B, a first stressor layer 241x may be formed to cover the top surface 110T of the active region 110 and the capping trench 240H.

In some embodiments, the first stressor layer 241x may be formed by using a plasma source. Specifically, the first stressor layer 241x may be formed by using, for example, at least one of a PECVD process, an HDP CVD process, an ICP CVD process, and a CCP CVD process.

The process of forming the first stressor layer 241x may be performed at a temperature of, for example, about 300° C. to about 700° C. A gas used in the process of forming the first stressor layer 241x may include, for example, at least one of SIH₄ gas, N₂ gas, and NH₃ gas.

When the first stressor layer 241x is formed by using the plasma source, a stress of the first stressor layer 241x may be controlled.

In some embodiments, the stress of the first stressor layer 241x may be controlled by adjusting a content ratio of silicon to nitrogen in the gas. In some other embodiments, the stress of the first stressor layer 241x may be controlled by adjusting a density of the plasma source.

Referring to FIG. 13C, a portion of the first stressor layer 241x may be etched to form a first stressor layer 241y. The etching process may be, for example, any one of a physical etching process (e.g., a sputter etching process), a chemical etching process (e.g., a reactive radical etching process), and a chemicophysical etching process (e.g., an RIE process, an MERIE process, a TCP etching process, and an ICP etching process).

A sidewall 241W of the first stressor layer 241y positioned in the vicinity of the capping trench 240H may be inclined due to the etching process.

Referring to FIG. 13D, a second stressor layer 242y may be formed on the first stressor layer 241y.

The second stressor layer 242y according to some embodiments may be formed to have a different stress from the first stressor layer 241y. In some embodiments, any one of the first and second stressor layers 241y and 242y may have a compressive stress, while the other thereof may have a tensile stress. For example, the first stressor layer 241y may have a compressive stress of about 0.1 GPa to about 3 GPs, and the second stressor layer 242y may have a tensile stress of about 0.1 GPa to about 3 GPa. In some other embodiments, the first stressor layer 241y may have a first compressive stress, while the second stressor layer 242y may have a second compressive stress different from the first compressive stress. for example, the first stressor layer 241y may have a compressive stress of about 0.1 GPa to about 1.5 GPs, and the second stressor layer 242y may have a compressive stress of about 1.6 GPa to about 3 GPa.

A content ratio of Si to N in a gas source used in a process of forming each of the first and second stressor layers 241y and 242y and/or a density of a plasma source may be differently controlled so that the first stressor layer 241y may have a different stress from the second stressor layer 242y.

Alternatively, the first stressor layer 241y may be formed by using a plasma source and the second stressor layer 242y may be formed by using a thermal ALD process so that the first and second stressor layers 241y and 242y having different stresses may be formed.

Referring to FIG. 13E, the first and second stressor layers 241y and 242y may be polished until the top surface 110T of the active region 110 is exposed. Thus, the capping layer 240 including first and second stressors 241 and 242 may be formed.

FIGS. 14A to 14D are cross-sectional views of process operations of a method of manufacturing the capping layer (refer to 340 in FIG. 3) according to another example embodiment. In FIGS. 14A to 14D, the same reference numerals are used to denote the same elements as in FIGS. 1A to 13E, and repeated descriptions thereof are omitted for brevity.

Referring to FIG. 14A, a first stressor layer 341x may be formed to cover a top surface 110T of an active region 110 and a capping trench 240H.

The first stressor layer 341x may be formed by using a plasma source. Specifically, the first stressor layer 341x may be formed by using, for example, at least one of a PECVD process, an HDP CVD process, an ICP CVD process, and a CCP CVD process.

In some embodiments, the first stressor layer 341x may be formed by using a similar process to the process of forming the stressor layers 241y and 242y described with reference to FIGS. 12A to 12D.

Referring to FIG. 14B, the first stressor layer 341x may be etched back to form a first stressor 341. Due to the etchback process, a top surface 341T of the first stressor 341 may be positioned at a lower level than the top surface 110T of the active region 110.

Referring to FIG. 14C, a second stressor layer 342x may be formed to cover the top surface 110T of the active region 110 and the top surface 341T of the first stressor 341.

In some embodiments, the second stressor layer 342x may be formed to have a different stress from the first stressor 341. In some embodiments, one of the first stressor 341 and the second stressor layer 342x may have a compressive stress, while the other thereof may have a tensile stress. In some other embodiments, the first stressor 341 may have a first compressive stress, while the second stressor layer 342x may have a second compressive stress different from the first compressive stress.

A content ratio of Si to N in a gas source used in a process of forming each of the first and second stressor layers 341x and 342x and/or a density of a plasma source may be differently controlled so that the first stressor 341 may have a different stress from the second stressor 342x.

Alternatively, the first stressor layer 341x may be formed by using a plasma source, and the second stressor layer 242x may be formed by using a thermal ALD process to have a different stress from the first stressor 341.

Referring to FIG. 14D, the second stressor layer 342x may be polished until the top surface 110T of the active region 110 is exposed, thereby forming the capping layer 340 including first and second stressors 341 and 342.

FIGS. 15A to 15C are cross-sectional views of process operations of a method of manufacturing the capping layer (refer to 440 in FIG. 4) according to another example embodiment. In FIGS. 15A to 15C, the same reference numerals are used to denote the same elements as in FIGS. 1A to 14D, and repeated descriptions thereof are omitted for brevity.

Referring to FIG. 15A, similar to that described above with reference to FIG. 11E, a semiconductor substrate 101 in which a word line 130 is buried may be prepared. A top surface 130T of the word line 130 may be located at a lower level than a top surface 110T of an active region 110 or a top surface 120T of a device isolation layer 120 so that a capping trench 440H may be defined.

Referring to FIG. 15B, a stressor layer 441x may be formed to cover the top surface 110T of the active region 110 and the capping trench 440H.

The stressor layer 441x may be formed by a plasma-enhanced atomic layer deposition (PEALD) process. In this case, the stressor layer 441x may have a seam 441Sx having a line shape, which tends to be vertical in a cross-sectional view.

In some embodiments, a plasma source used in the PEALD process may be, for example, direct plasma or remote plasma, and a gas used in the PEALD process may include at least one of NH₃ gas, Ar gas, and N₂ gas.

In some embodiments, the process of forming the stressor layer 441x may be performed at a temperature of, for example, about 300° C. to about 700° C.

When the stressor layer 441x is formed by using a PEALD process, even if the capping trench 440H has a fine width 440HW, a high-quality stressor layer 441x may be formed, and a stress of the stressor layer 441x may be controlled.

In some embodiments, the stress of the stressor layer 441x may be controlled by adjusting a content ratio of the gas source. In some other embodiments, the stress of the stressor layer 441x may be controlled by adjusting a density of the plasma source.

Referring to FIG. 15C, the stressor layer 441x may be polished until the top surface 110T of the active region 110 is exposed, thereby forming the capping layer 440 including a stressor 441.

FIGS. 16A to 16D are cross-sectional views of process operations of a method of manufacturing the capping layer (refer to 540 in FIG. 5) according to another example embodiment. In FIGS. 16A to 16D, the same reference numerals are used to denote the same elements as in FIGS. 1A to 15C, and repeated descriptions thereof are omitted for brevity.

Referring to FIG. 16A, similar to that described above with reference to FIG. 11E, a semiconductor substrate 101 in which a word line 130 is buried may be prepared. A top surface 130T of the word line 130 may be located at a lower level than a top surface 110T of an active region 110 or a top surface 120T of a device isolation layer 120 so that a capping trench 540H may be defined.

Referring to FIG. 16B, a first stressor layer 541x may be formed to cover the top surface 110T of the active region 110 and the capping trench 540H.

Similar to the stressor layer 441x described with reference to FIG. 15B, the first stressor layer 541x may be formed by using a PEALD process. In this case, the first stressor layer 541x may have a seam 541Sx having a line shape, which tends to be vertical in a cross-sectional view.

Referring to FIG. 16C, the first stressor layer 541x may be etched back to form a first stressor 541 having a seam 541S. Due to the etchback process, a top surface 541T of the first stressor 541 may be positioned at a lower level than the top surface 110T of the active region 110.

Referring to FIG. 16D, a second stressor 542 may be formed to cover the top surface 541T of the first stressor 541. Thus, the capping layer 540 including the first and second stressors 541 and 542 having different stresses may be formed.

Similar to that described with reference to FIGS. 14C and 14D, the formation of the second stressor 542 may include forming a second stressor layer (not shown) to cover the top surface 110T of the active region 110 and the top surface 541T of the first stressor 541 and polishing the second stressor layer.

FIGS. 17A to 17D are cross-sectional views of process operations of a method of manufacturing the capping layer (refer to 640 in FIG. 6) according to another example embodiment. In FIGS. 17A to 17D, the same reference numerals are used to denote the same elements as in FIGS. 1A to 16D, and repeated descriptions thereof are omitted for brevity.

Referring to FIG. 17A, similar to that described above with reference to FIG. 11E, a semiconductor substrate 101 in which a word line 130 is buried may be prepared. A top surface 130T of the word line 130 may be located at a lower level than a top surface 110T of an active region 110 or a top surface 120T of a device isolation layer 120 so that a capping trench 540H may be defined.

Referring to FIG. 17B, a first stressor layer 641x may be formed to cover the top surface 110T of the active region 110 and the capping trench 640H.

Similar to the stressor layer 441x described above with reference to FIG. 15B, the first stressor layer 641x may be formed by using a PEALD process. However, the first stressor layer 641x may be different from the stressor layer (refer to 441x in FIG. 15B) in that the first stressor layer 641x does not completely fill the capping trench 640H.

Referring to FIG. 17C, a second stressor layer 642x may be formed to cover the top surface 641T of the first stressor layer 641x. The second stressor layer 642x may have a seam 642Sx having a line shape, which tends to be vertical in a cross-sectional view.

The second stressor layer 642x may have a different stress from the first stressor layer 641x. To this end, the first stressor layer 641x may be formed by using a PEALD process, and the second stressor layer 642x may be formed by using a thermal ALD process.

Alternatively, both the first and second stressor layers 641x and 642x may be formed by using a PEALD process. A content ratio of silicon to nitrogen in a gas source used in a process of forming each of the first and second stressor layers 641x and 642x and/or a density of a plasma source may be differently controlled so that the second stressor layer 642x may have a different stress from the first stressor layer 641x.

Referring to FIG. 17D, the first and second stressor layers 641x and 642x may be polished until the top surface 110T of the active region 110 is exposed, thereby forming a capping layer 640 including first and second stressors 641 and 642.

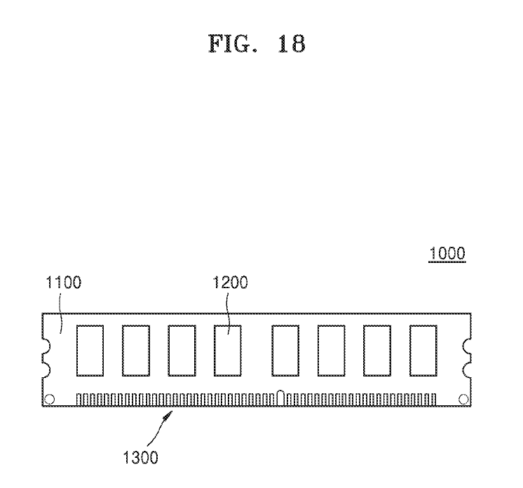

FIG. 18 is a diagram of a memory module 1000 including a semiconductor device according to various example embodiments.

Referring to FIG. 18, the memory module 1000 may include a memory module substrate 1100 and a plurality of memory devices 1200 and a plurality of terminals 1300 positioned on the memory module substrate 1100.

The memory module substrate 1100 may include a printed circuit board (PCB) or a wafer.

At least one of the memory devices 1200 may be one of the semiconductor devices (refer to 100, 200, 300, 400, 500, 600, 700, and 800 in FIGS. 1A to 8) according to various example embodiments or a semiconductor package including one of the semiconductor devices.

Furthermore, a process of manufacturing the memory devices 1200 may include the process of manufacturing the semiconductor devices as described with reference to FIGS. 11A to 17D.

The plurality of terminals 1300 may include a conductive metal. Each of the terminals 1300 may be electrically connected to each of the memory devices 1200.

Since the memory module 1000 includes a semiconductor device having a low channel resistance so as to increase a drain current, module performance of the memory module 1000 may be improved.

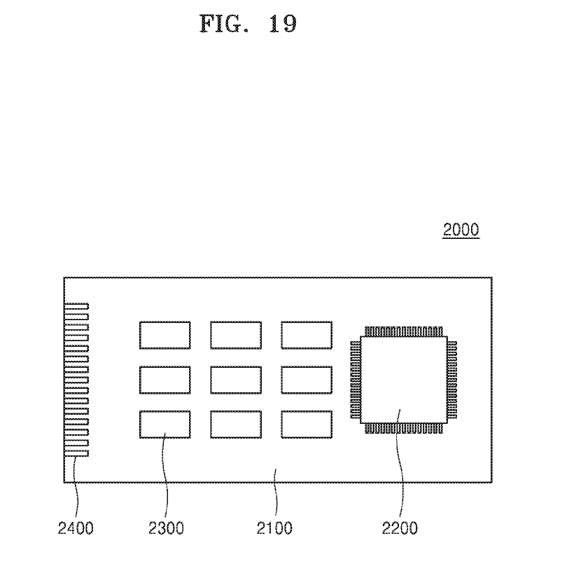

FIG. 19 is a diagram of a memory card having a semiconductor device 2000 according to various example embodiments.

Referring to FIG. 19, the memory card 2000 according to an example embodiment may include memory devices 2300 mounted on a memory card substrate 2100.

At least one of the memory devices 2300 may be one of the semiconductor devices (refer to 100, 200, 300, 400, 500, 600, 700, and 800 in FIGS. 1A to 8) according to various example embodiments or a semiconductor package including one of the semiconductor devices.

Furthermore, a process of manufacturing the memory devices 2300 may include the process of manufacturing the semiconductor devices as described with reference to FIGS. 11A to 17D.

The memory card 2000 may further include a microprocessor (MP) 2200 mounted on the memory card substrate 2100. Input/output (I/O) terminals 2400 may be positioned on at least one side of the memory card substrate 2100.

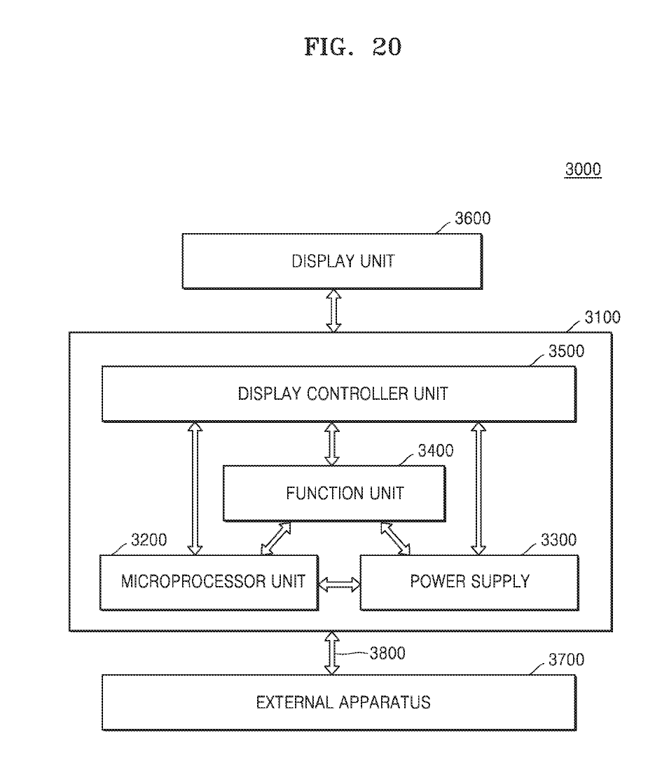

FIG. 20 is a diagram of an electronic system including at least one of semiconductor devices according to various example embodiments.

Referring to FIG. 20, the electronic system 3000 may include a body 3100. The body 3100 may include an MP unit 3200, a power supply 3300, a function unit 3400, and/or a display controller unit 3500. The body 3100 may be a system board or a mother board having a printed circuit board (PCB). The MP unit 3200, the power supply 3300, the function unit 3400, and the display controller unit 3500 may be mounted on the body 3100.

A display unit 3600 may be positioned on a top surface of the body 3100 or outside the body 3100. For example, the display unit 3600 may be positioned on a surface of the body 3100 and display an image processed by the display controller unit 3500.

The power supply 3300 may receive a voltage from an external power source, divide the predetermined or desired voltage into voltages having various voltage levels, and supply the voltages to the MP unit 3200, the function unit 3400, and the display controller unit 3500. The MP unit 3200 may receive a voltage from the power supply 3300 and control the function unit 3400 and the display unit 3600.

The function unit 2340 may implement various functions of the electronic system 3000. For example, when the electronic system 3000 is a mobile electronic product, such as a portable phone, the function unit 3400 may include various elements capable of wireless communication functions, such as the output of an image to the display unit 3600 or the output of a voice to a speaker, by dialing or communication with an external apparatus 3700. When the function unit 2340 includes a camera, the function unit 2340 may serve as an image processor. When the electronic system 3000 is connected to a memory card to increase capacity, the function unit 3400 may be a memory card controller. The function unit 3400 may exchange signals with the external apparatus 3700 through a wired or wireless communication unit 3800. Also, when the electronic system 3000 needs a universal serial bus (USB) to expand functions thereof, the function unit 3400 may serve as an interface controller. At least one of the MP unit 3200 and the function unit 3400 may include at least one of the semiconductor devices (refer to 100, 200, 300, 400, 500, 600, 700, and 800 in FIGS. 1A to 8) according to various embodiments of the inventive concepts.

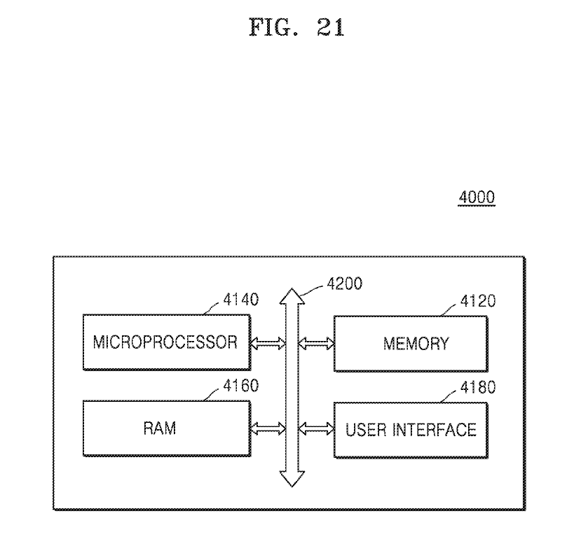

FIG. 21 is a diagram of another electronic system including at least one of semiconductor devices according to various example embodiments.

Referring to FIG. 21, the electronic system 4000 may include at least one of the semiconductor devices (refer to 100, 200, 300, 400, 500, 600, 700, and 800 in FIGS. 1A to 8) according to various embodiments of the inventive concepts.

The electronic system 4000 may be used to manufacture a mobile device or a computer. For example, the electronic system 4000 may include a memory system 4120 and an MP 4140, a RAM 4160, and a user interface 4180, which may communicate data via a bus 4200.

The MP 4140 may program and control the electronic system 4000. The RAM 4160 may be used as an operation memory of the MP 4140. For example, the MP 4140 or the RAM 4160 may include at least one of the semiconductor devices (refer to 100, 200, 300, 400, 500, 600, 700, and 800 in FIGS. 1A to 8) according to various embodiments of the inventive concepts. The MP 4140, the RAM 4160, and/or other elements may be assembled in a single package.

The user interface 4180 may be used to input data to the electronic system 4000 or output data from the electronic system 4000.

The memory system 4120 may store operating codes of the MP 4140, data processed by the microprocessor 4140, or external input data. The memory system 4120 may include a controller and a memory device.

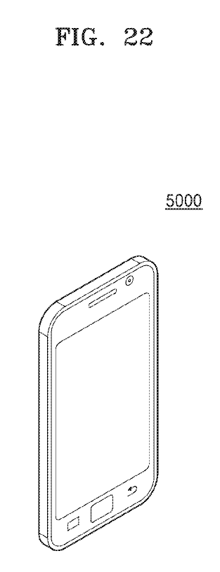

FIG. 22 is a schematic diagram of a wireless mobile phone 5000 according to embodiments of the inventive concepts.

Referring to FIG. 22, the wireless mobile phone 5000 may be interpreted as a tablet personal computer (PC). Furthermore, at least one of the semiconductor devices (refer to 100, 200, 300, 400, 500, 600, 700, and 800 in FIGS. 1A to 8) according to various embodiments of the inventive concepts may be used not only for a tablet PC but also for a portable computer such as a laptop computer, an MPEG-1 audio layer 3 (MP3) player, an MP4 player, a navigation device, a solid-state disk (SSD), a desktop computer, or electronic devices for automotive and household uses.

While the inventive concepts have been particularly shown and described with reference to example embodiments thereof, it will be understood that various changes in form and details may be made therein without departing from the spirit and scope of the following claims.

What is claimed is:

1. A method of manufacturing a semiconductor device, the method comprising:
forming a word line trench in an active region;
forming a gate dielectric layer to cover at least a portion of the word line trench;
forming a word line within the word line trench to define a capping trench; and
forming a stressor having a compressive stress within the capping trench,
wherein the stressor is formed by using a plasma source.

2. The method of claim 1, wherein the stressor is formed by using at least one of a plasma-enhanced chemical vapor deposition (PECVD) process, a high-density plasma CVD (HDP CVD) process, an inductively coupled plasma CVD (ICP CVD) process, and a capacitor-coupled plasma CVD (CCP CVD) process.

3. The method of claim 1, wherein the stressor has a compressive stress of about 0.1 GPa to about 3 GPa.

4. The method of claim 1, wherein the forming of the stressor comprises:
forming a first stressor layer to cover the capping trench;
etching the first stressor layer; and
forming a second stressor layer on the etched first stressor layer.

5. The method of claim 4, further comprising performing a planarization process on the first and second stressor layers to expose a top surface of the active region.

6. The method of claim 1, wherein the forming of the stressor comprises:
forming a stressor layer by using a plasma-enhanced atomic layer deposition (PEALD) process to cover the capping trench; and
performing a planarization process on the stressor layer to expose a top surface of the active region.

7. A method of manufacturing a semiconductor device, the method comprising:
forming a word line trench in an active region;
forming a gate dielectric layer to cover at least a portion of the word line trench;
forming a word line within the word line trench to define a capping trench; and
forming a capping layer to cover the capping trench,
wherein the capping layer comprises a first stressor and a second stressor having different stresses, and
at least one of the first and second stressors is formed by using a plasma source.

8. The method of claim 7, wherein a sidewall of the first stressor is inclined.

9. The method of claim 7, wherein one of the first and second stressors has a compressive stress, and the other has a tensile stress.

10. The method of claim 7, wherein the first stressor has a first compressive stress, and the second stressor has a second compressive stress different from the first compressive stress.

11. The method of claim 7, wherein one of the first and second stressors is formed by using at least one of a PECVD process, an HDP CVD process, an ICP CVD process, a CCP CVD process, and a PEALD, and the other one of the first and second stressors is formed by a thermal atomic layer deposition (ALD) process.

12. The method of claim 7, wherein the first stressor has a compressive stress, and a side surface of the first stressor is in contact with the gate dielectric layer.

13. The method of claim 7, wherein the first stressor has a compressive stress, and a side surface of the first stressor is in contact with the word line trench.

14. The method of claim 7, wherein at least one of the first stressor and the second stressor is formed without a seam.

15. The method of claim 7, wherein at least one of the first stressor and the second stressor is in contact with the top surface of the word line.

16. A method of manufacturing a semiconductor device, the method comprising:
forming a trench in an active region;
forming a dielectric layer to fill at least a portion of the trench;
forming an address line within the trench to define a shallower capping trench; and
using a plasma source to form at least one stressor having a compressive stress within the shallower capping trench.

17. The method of claim 16, wherein the plasma source is at least one of a plasma-enhanced chemical vapor deposition (PECVD) source, a high-density plasma CVD (HDP CVD) source, an inductively coupled plasma CVD (ICP CVD) source, and a capacitor-coupled plasma CVD (CCP CVD) source.

18. The method of claim 1, wherein the at least one stressor has a compressive stress of about 0.1 GPa to about 3 GPa.

19. The method of claim 16, wherein the forming of the at least one stressor comprises:
forming a first stressor layer in the shallower capping trench;
etching the first stressor layer; and
forming a second stressor layer on the etched first stressor layer.

20. The method of claim 19, wherein one of the first and second stressor layers has a compressive stress and the other of the first and second stressor layers has a tensile stress.
